(19) United States
(12) Patent Application Publication
(10) Pub. No.: US 2024/0319599 A1
(43) Pub. Date: Sep. 26, 2024

(54) GAS RELEASING UNDERLAYERS FOR PHOTOPATTERNABLE ORGANOMETALLIC RESIST

(71) Applicants: Inpria Corporation, Corvallis, OR (US); JSR Corporation, Tokyo (JP)

(72) Inventors: Kazunori Sakai, Tokyo (JP); Tatsuya Kasai, Tokyo (JP); Akitaka Nii, Tokyo (JP); Peter de Schepper, Winegem (BE)

(21) Appl. No.: 18/125,934

(22) Filed: Mar. 24, 2023

(51) Int. Cl. G03F 7/11; C09D 7/63; C09D 183/16

(52) U.S. Cl. CPC G03F 7/11; C09D 7/63; C09D 183/16

(57) ABSTRACT

Gas releasing compositions that can facilitate improved patterning of organometallic resists are described. The gas releasing compositions can release water, carbon dioxide, or alcohols in response to radiation or heating. A film-forming composition is composed of a flowable blend of a reactive gas releasing moiety, a matrix forming species, an organic solvent, and an optional activating agent. An underlayer composition is composed of a blend of a reactive gas releasing moiety, a polymer matrix and an optional activating additive. Multilayer structures are described based on organometallic radiation sensitive patterning compositions, such as alkyl tin oxo-hydroxo compositions, which are placed over a gas releasing underlayer formed on a substrate, such as a semiconductor wafer. Methods for patterning multilayer structures are also described.

### FIELD OF THE INVENTION

The invention relates to radiation patternable coatings having an underlayer of a gas releasing composition that can facilitate improved patterning.

### BACKGROUND OF THE INVENTION

Semiconductor fabrication generally consists of iterative processing steps comprising deposition, etching, photopatterning, pattern transfer, and the like. Photopatterning is generally performed through the process of lithography wherein a photosensitive material (i.e., a photoresist) is irradiated with an appropriate radiation source, such as ultraviolet (UV), extreme ultraviolet (EUV), or an ion beam, to induce solubility changes in the irradiated material relative to the non-irradiated material. Improvements in this photolithographic process are generally desired to reduce costs of device fabrication, and to reduce component size, and to improve pattern fidelity, and device performance, among others.

In the effort to continue to reduce device sizes produced from photolithography, photolithographic systems have been developed to use EUV which has very short wavelengths that can allow very small image formation and high-resolution patterns. Organometallic coatings have been shown to be useful as suitable photoresist materials for achieving high-resolution patterning and are very promising for commercial use for patterning with EUV lithography, as well as for electron beam patterning. To fully take advantage of organometallic resists, improvements to and innovations of ancillary materials, such as underlayers, are desired to enable new improvements in resist pattern fidelity.

### SUMMARY OF THE INVENTION

In a first aspect, a film-forming composition is described which includes a flowable blend of a reactive gas releasing moiety, a matrix forming species, an organic solvent, and an optional activating additive. The reactive gas releasing moiety releases metal ligand forming molecules in response to radiation or heat. The activating additive is present if the gas releasing moiety releases the reactive gas upon activation stimulated by the activating additive. The matrix forming species comprises a polymer and/or one or more polymer precursors.

In a further aspect, a composition is described which includes a blend of a reactive gas releasing moiety, a polymer matrix, and an optional activating additive, wherein the reactive gas releasing moiety releases metal ligand forming molecules in response to radiation or heat. The activating additive is present if the gas releasing moiety releases the reactive gas upon activation stimulated by the activating additive. The reactive gas releasing moiety is bound to the polymer matrix or is blended within the polymer matrix.

In a further aspect, a multilayer structure is described which includes a substrate with a surface, an underlayer material over at least a portion of the substrate surface, and an organometallic patterning material that is radiation sensitive over at least a portion of the underlayer material. The underlayer material comprises a polymer and a reactive gas releasing moiety, which may or may not be bonded to the polymer. The reactive gas releasing moiety releases a metal ligand forming molecule in response to radiation and/or heat.

In a further aspect, a method for patterning a radiation sensitive organometallic composition is described which includes coating a composition comprising a reactive gas releasing moiety onto a surface of a substrate to form an underlayer material that covers at least a portion of the surface to form an underlayer structure; depositing an organometallic patterning material on the underlayer structure to form a multilayer structure; irradiating the multilayer structure according to a selected pattern to form a latent image; heating the irradiated multilayer structure with the latent image as a post-exposure bake, wherein the underlayer material releases a metal ligand forming molecule in response to irradiation or heating through the underlayer material or a portion thereof, wherein the organometallic patterning material or portion thereof reacts with the metal ligand forming molecule; and developing the latent image after the post exposure bake and reaction with the metal ligand forming molecule.

Another aspect of the invention pertains to underlayer materials that can release a species capable of reacting with a metal oxide photoresist.

Another aspect of the invention pertains to an underlayer material that releases CO₂ during heating and/or irradiation.

In a further aspect, a polymeric material is described which includes a CO₂ releasing moiety and a polymer material. The CO₂ releasing moiety releases CO₂ in response to radiation or heat. The polymer material provides a matrix for the CO₂ releasing moiety.

Another aspect of the invention pertains to an underlayer material that releases H₂O during heating and/or irradiation.

### BRIEF DESCRIPTION OF THE DRAWINGS

FIG. 1 is a side-on view of a multilayer stack of a substrate, an underlayer, and an irradiated photoresist.

FIG. 2A is a side-on view of the multilayer stack of FIG. 1 in which the underlayer below the irradiated regions of the photoresist releases gas.

FIG. 2B is a side-on view of a multilayer stack of a substrate, an underlayer, and a photoresist in which the underlayer uniformly releases gas into the photoresist.

FIG. 3 is a cartoon illustrating the underlayer-mediated crosslinking of irradiated organotin material via an underlayer-released reactive gas species.

FIG. 4 is a plot of the relative amount of CO₂ generated per sample for a set of five underlayer formulations baked at 220° C. for 1 minute.

FIG. 5 is a plot of the mass percent as a function of temperature for a set of underlayer formulations.

### DETAILED DESCRIPTION

New compositions are herein described to provide underlayers that can enable improved processing of organometallic photoresists. Underlayers can be useful in semiconductor lithographic processing where photoresist materials are typically deposited on the surface of the underlayer material to form a multilayer structure that then undergoes subsequent processing, such as one or more heating, exposure to radiation, development, etch, and so forth. The objective then is to form a pattern according to a prescribed design. The underlayer materials described herein are thermally and/or radiation sensitive such that they can release vapor species, such as H₂O, alcohol, and/or CO₂, that can react with the photoresist within the multilayer structure. Generally, the released reactive gas comprises metal ligand forming molecules that can stabilize the metal oxo-hydroxo network and facilitate release of cleaved organic ligands when contacting irradiated regions of the organometallic patterning composition. Depending on the mechanism of vapor release, the timing of the release can coincide with an appropriate time to achieve the desired process improvement. The reaction with the released species can alter the patterning properties to facilitate and/or improve the patterning process. The use of the underlayer can be folded into the overall process flow for appropriate commercial utility.

The underlayers comprise compositions selected to release gas based on heat and/or radiation. The underlayers may also comprise a matrix, such as a polymer, to interface with the gas releasing composition. The released gas compounds can diffuse into the overlayer of patterning compositions. If the gas is released prior to irradiation, such as through a pre-irradiation bake, the gas can modify patterning composition across the layer, which would be intended to alter the organometallic composition to enhance the radiation based patterning through an adjustment of the material properties. If the gas is released during or following irradiation, the gas can differentially alter the irradiated and/or non-irradiated patterning composition. If the gas is released by the radiation, the gas release would be concentrated under the irradiated organometallic composition. If the gas is released thermally following irradiation, the gas generally is released uniformly along the layer, but since the patterning composition is altered between the irradiated and non-irradiated regions, the gas can react differently with the irradiated and non-irradiated composition. The interaction with the gas can increase the development contrast to improve patterning performance.

Conventional photoresists are composed of organic materials, especially polymers, and have found use in various applications, such as lithography. A great deal of attention and effort has been devoted to improving the performance of conventional polymer photoresists, such as boosting their photoefficiency to extreme ultraviolet (EUV) radiation, resolution, and pattern fidelity (roughness). Accordingly, improvements to underlayer materials have been made to improve the performance of multilayer stacks comprising conventional photoresists. However, less attention has been given to improving underlayer materials for use with organometallic and/or metal oxide photoresists.

Metal oxide and organometallic photoresists, particularly those comprising Sn, have been shown to have many promising properties for use in high resolution lithography processes, such as high absorption of EUV photons, very high resolution, high pattern fidelity, and high etch resistance. For example, organometallic radiation sensitive resists have been developed based on alkyl tin compositions, such as alkyltin oxide hydroxide, approximately represented by the formula R_{z}SnO_{(2-z/2-x/2)}(OH)ₓ, where 0<x<3, 0<z≤2, x+z≤4, and R is a hydrocarbyl group forming a carbon bond with the tin atom. Particularly effective forms of these compositions are monoalkytin oxide hydroxide, in which z=1 in the above formula. Alkyl tin based photoresist materials are further described in U.S. Pat. No. 9,310,684 (herein the '684 patent) to Meyers et al., entitled “Organometallic Solution Based High Resolution Patterning Compositions,” U.S. Pat. No. 10,642,153 (herein the '153 patent) to Meyers et al., entitled “Organometallic Solution Based High Resolution Patterning Compositions and Corresponding Methods,” and U.S. Pat. No. 10,228,618 (herein the '618 patent) to Meyers et al., entitled “Organotin Oxide Hydroxide Patterning Compositions, Precursors, and Patterning,” each of which are incorporated herein by reference. Organotin patterning compositions are described further below

While alkyl tin compositions are demonstrating particularly promising results other organometallic resist compositions have been explored. See, for example, U.S. Pat. No. 9,176,377 to Stowers et al., entitled “Patterned Inorganic Layers, Radiation Based Patterning Compositions and Corresponding Methods,” published U.S. patent application 2013/0224652 to Bass et al., entitled “Metal Peroxo Compounds with Organic Co-ligands for Electron Beam, Deep UV, and Extreme UV Photoresist Applications,” and published U.S. patent application 2002/0076495 to Maloney et al., entitled “Method of Making Electronic Materials,” all of which are incorporated herein by reference. Other organometallic patterning compositions based on various metals are described in published U.S. Pat. No. 9,372,402B2 to Freedman et al., entitled “Molecular Organometallic Resists for EUV,” incorporated herein by reference. Resists with metal oxide particles having organic coatings are described in published U.S. patent application 2015/0234272A1 to Sarma et al., entitled “Metal Oxide Nanoparticles and Photoresist Compositions,” incorporated herein by reference. In general, the underlayer materials described herein can be useful generally for organometallic resists.

In general, organotin photoresist materials comprise radiation-sensitive organic ligands that are bound to the Sn atoms through Sn—C and/or Sn-carboxylate bonds. While not wanting to be limited by theory, it is generally thought that irradiating the organotin material with EUV radiation causes the radiation-sensitive bonds to be severed, and can therefore provide for additional cross-linking sites, thereby leading to increased condensation between tin atoms and promoting network formation of Sn—O—Sn bonds within the irradiated regions. Thus, the irradiated regions of the organotin photoresist are generally more condensed relative to the non-irradiated regions. After radiation exposure, such as EUV exposure and subsequent processing, the non-irradiated regions substantially retain the Sn—C and/or Sn-carboxylate bonds to organic ligands whereas the irradiated regions can have substantially less. Therefore, the non-irradiated regions are generally more hydrophobic than the irradiated regions and selective development of either region can be achieved by a suitable development process.

It can therefore be beneficial to introduce H₂O, alcohol, CO₂, and/or other reactive gas capable of reacting with the irradiated photoresist to further drive an increase in chemical contrast between the irradiated and non-irradiated regions and, thus, developer contrast. In general, the reactive gas comprise metal ligand forming molecules. The present invention is directed to underlayers that can enhance chemical contrast within the organometallic photoresist.

The effect of CO₂ and other reactive gas species in the process atmosphere on the lithographic performance of the organotin photoresist has been described in published U.S. Patent Application 2021/0271170 to Telecky et. al, entitled “Process Environment for Inorganic Resist Patterning”, incorporated herein by reference. Processing with appropriate concentrations of atmospheric CO₂ was found to decrease the radiation dose to achieve a particular feature size. For organotin photoresists, and while not wanting to be limited by theory, it is believed that the irradiated regions of the material can react with and/or incorporate H₂O, CO₂, and/or other species, to form, for example, hydroxides, oxides, carbonates and/or bicarbonates that can enhance developer contrast between the irradiated and non-irradiated regions of the material.

By reacting the irradiated material with a reactive gas, developer contrast can be improved between the irradiated and non-irradiated regions. This improvement in developer contrast can then enable developer compositions and processes that can better remove unwanted material, such as scum and/or microbridges, to yield lower defect patterns. Alternatively, or additionally, the improved developer contrast can result in lower patterning doses required for a desired pattern due to reduced solubility of irradiated material.

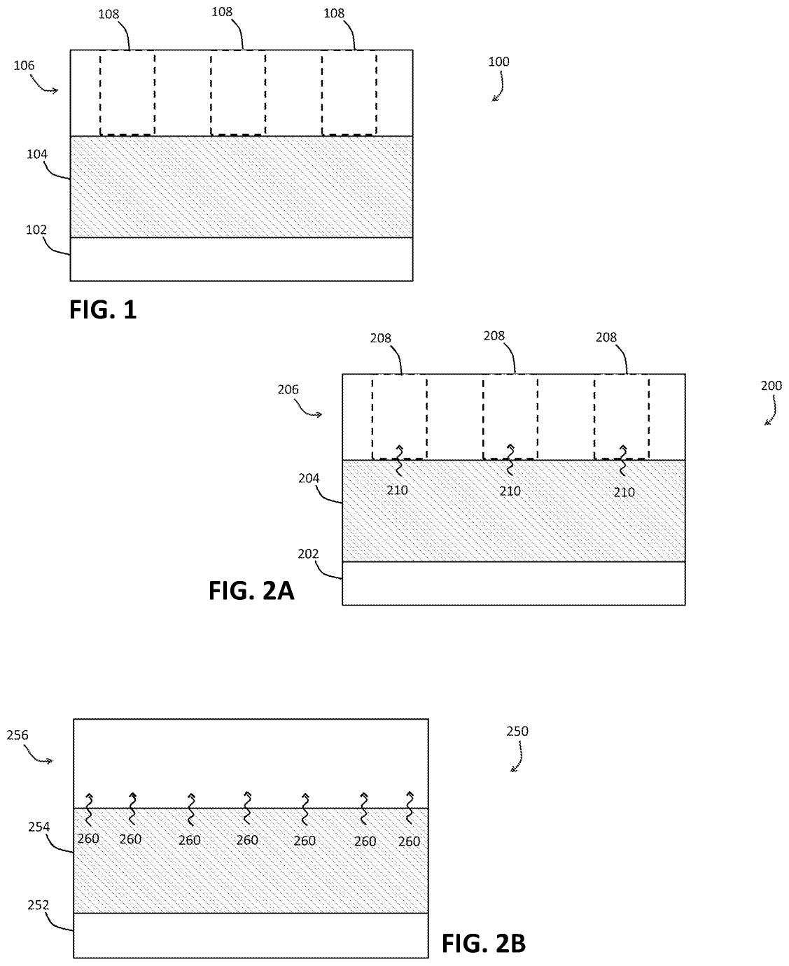

FIG. 1 schematically depicts a side-on view of multilayer structure 100 which has substrate 102, underlayer 104, and irradiated photoresist 106. Irradiated photoresist 106 has a latent image with irradiated photoresist regions 108 in a pattern. For organotin photoresists, as detailed above, irradiation results in cleavage of Sn—C bonds to result in a lower C:Sn ratios in the irradiated regions compared to the non-irradiated regions. Generally, higher irradiation doses leads to lower C:Sn ratios and, after irradiation, the irradiated regions can react with ambient humidity to drive hydrolysis and condensation processes to afford an increase in Sn—OH and/or Sn—O—Sn concentration in the irradiated regions.

FIG. 2A schematically depicts a side-on view of multilayer structure 200 which has substrate 202, underlayer 204, and irradiated photoresist 206. Irradiated photoresist 206 has a latent image with irradiated photoresist regions 208 in a pattern. Underlayer 204 can release reactive gas 210 into irradiated photoresist regions 208. Reactive gas 210 can be capable of coordinating with, reacting with, and/or bonding with Sn moieties within irradiated photoresist regions 208. FIG. 2B schematically depicts a side-on view of multilayer structure 250 which has substrate 252, underlayer 254, and photoresist 206. Photoresist 206 may be irradiated or unirradiated. Underlayer 254 can release reactive gas 260 into photoresist 206. In some embodiments, the underlayer may release species uniformly from its bulk. The bulk release is generally based on thermal release of the reactive gas. In other embodiments, the underlayer may release species only upon irradiation. In some embodiments, the reactive gas may be substantially unreactive towards the non-irradiated regions of the resist.

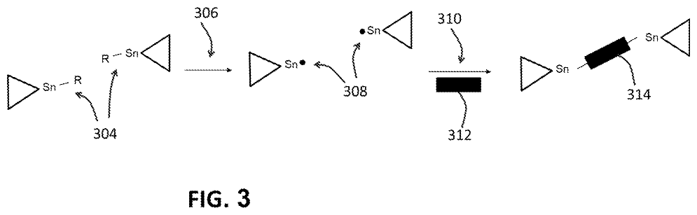

In some embodiments, the reactive gas released by the underlayer can comprise gases with at least one oxygen atom. Suitable examples of released species are CO₂, ROH and H₂O. Referring to FIG. 3, organotin photoresist material 304 comprises Sn—R bonds that are cleaved by radiation and/or heating 306 to leave active sites 308 capable of reacting 310 with underlayer-released reactive gas 312 to form linkage 314 between tin atoms, although alternatively reactive gas 312 can bond to a single Sn atom while still contributing to stabilization and hydrophilic nature of the material. The underlayer materials and compositions disclosed herein can release a reactive gas that can migrate into the irradiated regions of the photoresist to coordinate and/or bond with the Sn atoms to therefore result in increased crosslinking.

The compositions providing the reactive vapor species are provided in the underlayer and may be combined with a matrix, such as a polymer. The use of a polymer matrix can provide a processing aid and may assist with providing a desirable surface for the deposition of the organometallic patterning composition. The reactive gas releasing moiety may or may not be bound to the matrix material. Some suitable reactive gas releasing compositions can be formed into the underlayer without a separate matrix material. As noted below, reactive moieties for releasing the reactive gas species can be formed into functional groups as a part of a larger composition. Unless the context clearly indicates otherwise, a reference to reactive gas releasing compound may encompass a reactive gas releasing moiety bound to a polymer or other matrix or matrix forming compound.

The release of the reactive gas releasing moieties can be incorporated into the overall patterning process. For radiation release reactive gas releasing moieties, these would be released during the irradiation step. While not wanting to be limited by theory, the reactive gas can diffuse through the organometallic patterning composition while the C—Sn bonds are being photolitically cleaved, which may promote corresponding reactions. Thermally released reactive gas can be released in pre-exposure bake steps and/or post irradiation bake steps. Any released vapor species may not escape the material readily, so any reactions with the released reactive gas can occur in due course to alter contrast enhancement between irradiated and non-irradiated regions of the patterning composition layer. Subsequent development of the radiation image can exploit the improved contrast enhancement to form the patterned structure.

### Underlayer Forming Compositions

The compositions for forming underlayer films disclosed herein are generally formed from a composition comprising a reactive gas releasing compound (A), one or more polymer and/or polymer-forming compositions (B), and a solvent (C). In some embodiments, the underlayer composition can further comprise optional components (D). Solvent (C) is used in forming the underlayers, and the solvent is removed following applying the coating. Optional component (D) may or may not be volatile, and this component may be identified as being no more than 10 wt % relative to the solvent (C). Total solvent is identified as the volatile component of the film forming precursor liquids, which would include solvent (C) and any volatile components of optional components (D) and are generally not limited as long as they meet the desired properties. Solvent (C) generally is selected based on solubilities of the polymer or polymerizable species and of the reactive gas releasing compounds (if they are not bound to the (B) components). Solvents can be aqueous (at least about 10 volume percent water) or organic (non-aqueous) and can comprise blends of compounds. Optional components (D) can comprise suitable soluble additives, such as crosslinking agents, viscosity modifiers, surfactants, and the like. Example 2 exemplifies trimethyl ortho formate as a volatile optional Component (D), as a dehydrating agent. The amount of solvent is generally selected to provide desired coating properties based on the deposition approach, such as spin coating, such that the liquid has the desired viscosity and the resulting coating has the desired dry thickness after solvent removal. Upon forming the underlayer and drying the underlayer, the solvent is removed along with any volatile optional component (D). The dry underlayer then comprises reactive gas releasing compound (A), polymer forming composition (B) and any non-volatile optional components (D). In some embodiments, the dry underlayer composition comprises from about 0.01 wt % to about 20 wt % of the reactive gas releasing moiety, from about 50 wt % to about 99 wt % of the matrix forming components, and from about 0 to about 50 wt % of the optional components, such as an activating additive. The proportions of each carry over into the dry composition from the corresponding relative amounts in the underlayer forming composition.

In some embodiments, the reactive gas releasing compound can comprise at least about 0.001 wt. % of the total dry composition, in some embodiments at least about 0.01 wt. % of the total dry underlayer composition, in some embodiments at least about 0.1 wt. % of the total composition, and in other embodiments at least about 0.5 wt. % to about 10 wt % of the total dry underlayer composition. To the extent that the gas releasing moiety is bonded to matrix material, generally a polymer, the weight contribution of the gas releasing moiety can be considered separately from the weight of the remaining portion of the matrix material for evaluating the relative weights with an appropriate division selected at a chain branch point. In some embodiments, the total solids content of the underlayer forming solution can be less than about 15 wt %, in further embodiments from about 0.1 wt % to about 12 wt %, and in other embodiments from about 0.25 wt % to about 10 wt %. Optional components (D) generally make up no more than about 15 wt % of the coating solution and in some embodiments from about 0.1 wt % to about 12 wt %. The remainder of the dry coating is polymer forming composition (B). Polymer forming composition (B) generally make up no more than about 15 wt % of the coating solution, in further embodiments from about 0.1 wt % to about 12 wt %, and in other embodiments from about 0.25 wt % to about 10 wt %. A person of ordinary skill in the art will recognize that additional ranges of component compositions within the explicit ranges above are contemplated and are within the present disclosure.

The compositions for forming a matrix for the underlayer films can generally comprise any suitable film-forming compositions, such as polymers, oligomers, F-containing compositions, Si-containing compositions, and the like, while also comprising a reactive gas releasing compound or a reactive gas releasing moiety bonded to a matrix forming moiety. Desirable matrix compositions form flat layers for the patterning compositions to be deposited on them and form good dispersions of the reactive gas releasing compositions (A). When the reactive gas releasing compound as described herein are included in the compositions for forming underlayer films, resist patterning improvements can be realized. Some examples of film-forming compositions used for forming underlayer compositions have been described in Published U.S. Patent Applications US2020/0354575A1 (hereafter the '575 application) by Seiko et. al, entitled “Film-forming composition, silicon-containing film, and resist pattern-forming method”, and US2021/0286267A1 (hereafter the '267 application) by Abe et. al, entitled “Composition, resist underlayer film, and resist pattern-forming method”, both of which are incorporated herein by reference.

### Reactive Gas Releasing Compound

Suitable compounds are described for incorporation into underlays for the release of metal ligand forming molecules, such as water, alcohol or carbon dioxide. Suitable classes of compounds are described along with specific species that can be incorporated. The following section describes incorporation of these compounds into an underlayer with a matrix material. In general, any of the classes of reactive gas releasing compound has bonds available that can form derivatives. Some derivatives can be benign, such as being possible, but not significantly altering processing or reactivity, such as addition of alkyl chains in appropriate contexts. Other derivatives may influence solubilities, such as the addition of polar groups to facilitate solubility in polar solvents or the addition of non-polar groups to facilitate solubility in non-polar solvents. Still other derivatives can provide functional groups allowing bonding to the matrix polymer before or during polymerization or crosslinking, and such attachment functional groups can be selected based on the polymer structure. Examples of suitable groups for addition reactions include, for example, alkenes, alkynes, carbonyl, or imine groups, although other groups can be suitable with appropriate reactions conditions, crosslinking agents and/or catalysts.

### Water Releasing Compounds

With respect to a first group of compounds, the reactive gas releasing compound is capable of releasing H₂O upon heating and/or irradiation. In some embodiments, the reactive gas releasing compound capable of releasing H₂O comprises a nitrobenzyl moiety with an adjacent hydroxyl group bound to the aromatic ring. The basic structure is shown in formulas A1-1 to A1-8 below and can be referred to as a 2-hydroxymethyl-1-nitrobenzene or a 2-nitrobenzyl alcohol group, which is radiation sensitive. The structures can have the general formula 4-(CH₂OH)-3-NO₂—C₆H₃—R, where R is hydrogen, COO⁻, bond to a polymer, or CR₁R²R³, where R₁₋₃ can individually be aromatic, cyclic, with heteroatoms in various structures with some embodiments shown below. In further embodiments, the reactive gas releasing compound capable of releasing H₂O comprises an onium salt compound where an onium ion supplies a counter ion for the H₂O releasing compound. Onium cations, such as triphenyl sulfonium cations can function as photoacid generators, while the anions function to release the gas species. The reactive gas releasing compound capable of releasing H₂O can be a polymer bound moiety or simply blended with the polymer. Some non-limiting suitable examples of reactive gas releasing compounds capable of releasing H₂O upon heating and/or irradiation are represented by the following compounds (A1-1) through (A1-15).

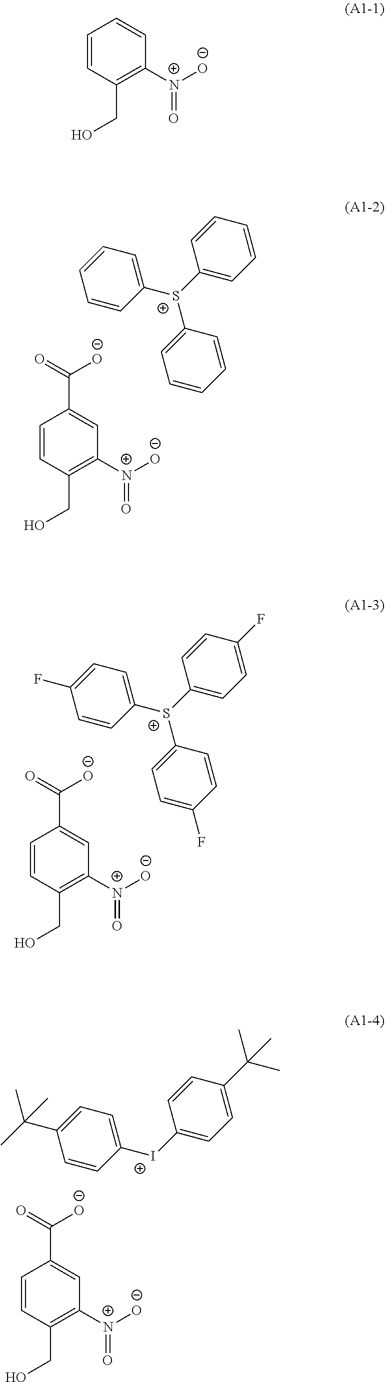

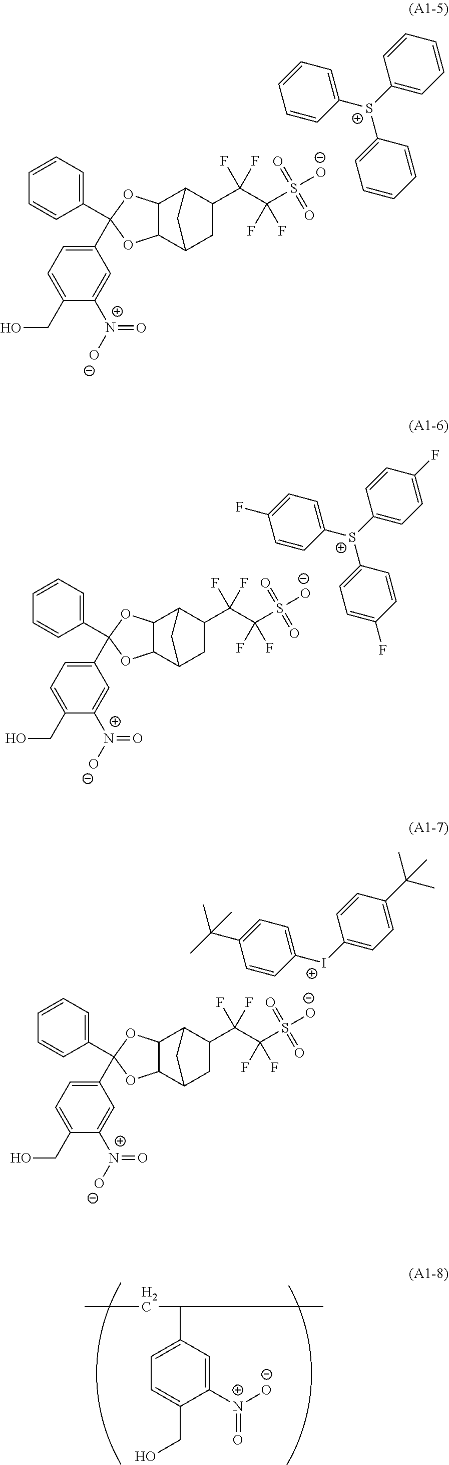

In acidic conditions, ethylene glycol and derivatives thereof can form acetaldehyde with release of a water molecule. In the undercoating, a photoacid generator (PAG) can be incorporated such that the generation of acid using radiation can then correspondingly result in the release of water. PAGs are discussed further below, and in combination with certain reactive gas releasing compounds are activating additives that cooperate in the release of the reactive gas. This mechanism for water release is relevant for compounds A1-9 to A1-11, which can also be appended to a polymer to stabilize their presence in the undercoating.

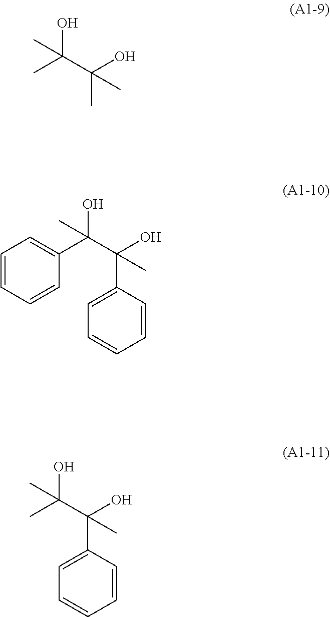

Alcohols can release water in acidic conditions along with the addition of heat. Along with the release of water, the organic product can be an ether or an alkene with double bonded carbon atoms. The acidic conditions can be applied with a PAG, an activating additive in the underlayer, such that acid is released upon irradiation. Heat can be applied simultaneously or subsequently to help drive the water release. Depending on the compound sufficient heat may be roughly 40° C. to 200° C. Representative compounds are shown as A1-12 and A1-13, and these can be incorporated into polymers if desired. Similarly, acid generated from PAG compounds can also stimulate dehydration of oximes (R═N—OH) to form nitriles. Representative compounds of this class are shown as A1-14 and A1-15.

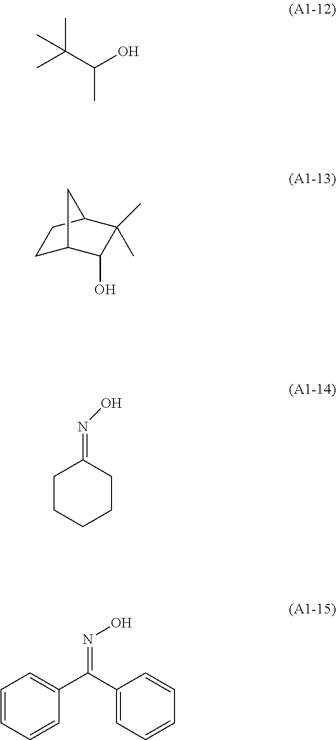

The synthesis of A1-2 compound is described in Example 1 below. Some of the compounds are readily available and can be adapted in an appropriate form or appropriate derivative to provide for incorporation into the underlayer structure. The remaining compounds can be synthesized based on this Example and knowledge in the art by a person of ordinary skill in the art.

The reactive gas releasing compounds shown above can release H₂O during irradiation of the underlayer-coated substrates with radiation, such as UV, EUV, ion-beams, and the like. During irradiation of metal oxide resist materials, such as organotin materials, reactive sites are generated that can react with H₂O to form metal hydroxide and/or metal oxide bonds that can drive improved solubility contrast between the irradiated and non-irradiated areas of the photoresist. Alternatively, or additionally, the reactive gas releasing compound can release water during a heating step, such as during a post-apply bake (PAB) or post-exposure bake (PEB).

As described below, the underlayer can comprise an orthoester. An orthoester generally can react with water to release an alcohol. Suitable alcohols for release include, for example, low molecular weight alcohols, such as methanol, ethanol, propanol or the like, which are volatile. Thus, the use of an orthoester can convert a water releasing agent to an alcohol reactant releasing agent in combination. This increases the range of reactant releasing agents to further comprise alcohol releasing agents based on this combination of agents.

### CO₂ Releasing Compounds

In some embodiments, the reactive gas releasing compound is capable of releasing CO₂ during heating and/or irradiation. In particular, the reactive gas releasing compound capable of releasing CO₂ can comprise an onium salt compound. Onium cations, such as triphenyl sulfonium cations can function as photoacid generators, while the anions function to release the gas species. In some embodiments, the reactive gas releasing compound capable of releasing CO₂ is a polymer bound moiety. Some CO₂ releasing moieties comprise a functional group with a Meldrum's acid group (2,2-dimethyl-1,3-dioxane-4,6-dione) that thermally decomposes or absorbs radiation to release carbon dioxide and acetone, while forming a reactive ketene. Other compounds incorporate a functional group based on propylene carbonate functional group. Another class of compounds involve photobase generators with an aromatic group bonded to an amine through a carbamate linkage. In some embodiments, the reactive gas releasing compound comprises more than one type of gas releasing moiety. Compounds from all three classes are exemplified. Some non-limiting suitable examples of reactive gas releasing compounds capable of releasing CO₂ upon heating and/or irradiation are represented by the following compounds (A2-1) through (A2-14).

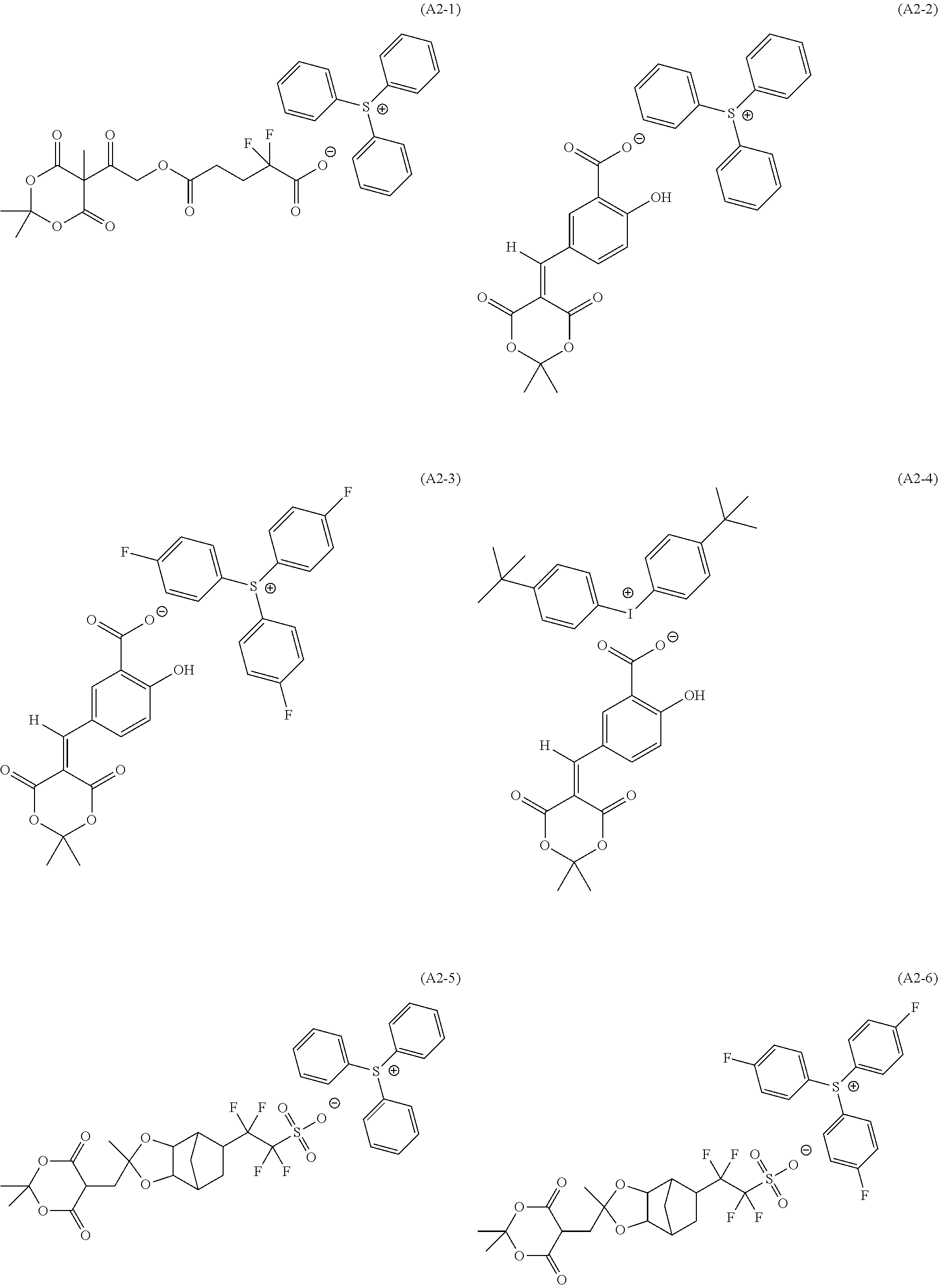

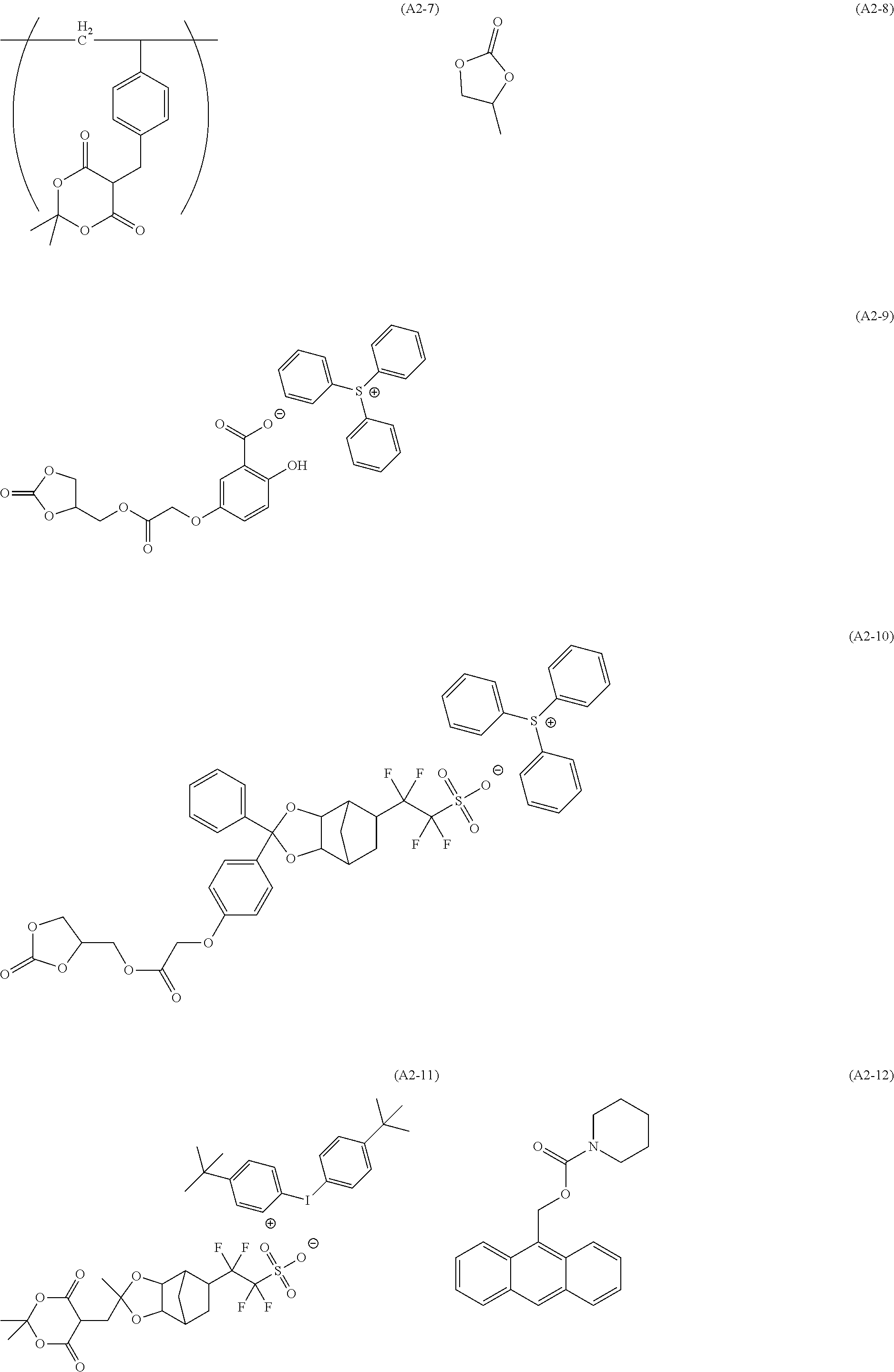

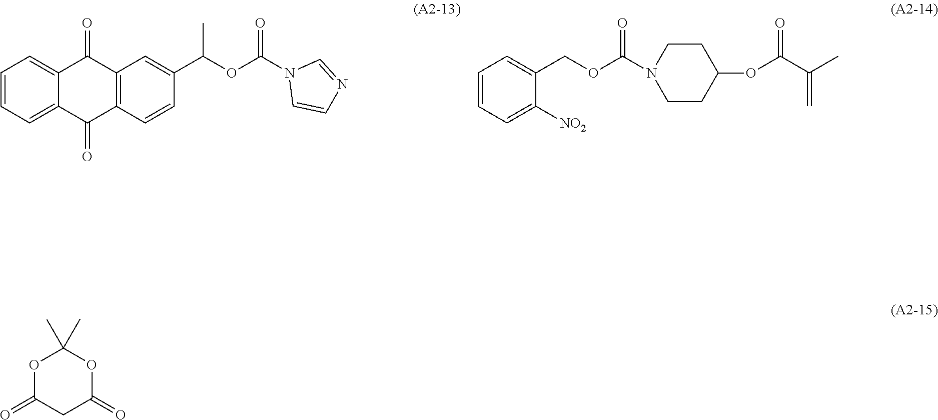

Meldrum's acid and propylene carbonate (A2-8) are commercially available. Both Meldrum's acid and propylene carbonate are exemplified below and examined for CO₂ release. A2-9 and A2-10 are derivative of propylene carbonate and can be synthesized based on the published U.S. patent application 2020/0393755A1 to Nemoto et al., entitled “Radiation-sensitive resin composition, resist pattern-forming method, compound, and method of controlling acid diffusion,” incorporated herein by reference. See compound C-1 in the '755 Nemoto application. . . . The synthesis of compounds A2-1 to A2-7 and A2-11 incorporate a Meldrum's acid functional group into the compounds. The general synthesis of Meldrum's acid and related compounds are described in published U.S. patent application 2008/0015365 A1 to Sato et al., entitled “Method for Producing 1,3-Dioxolan-4.6-Dione Compound,” incorporated herein by reference.

Photobase generators are described generally in U.S. Pat. No. 8,957,212 B2 to Kuramoto et al. (hereinafter the '212 patent), entitled “Photobase Generator,” incorporated herein by reference. The '212 patent explicitly describes compound A2-12 and genus covering A2-13 with a closely related species. A2-12 to A2-14 are exemplified below and examined for CO₂ release. Photobase generators are also described in Arimitsu et al., “Application to Photoreactive Materials of Photochemical Generation of Superbases with High Efficiency Based on Photodecarboxylation Reactions,” Chemical Materials 2013, 25, 4461-4463, incorporated herein by reference. The photobase generator in the Arimitsu article also releases CO₂.

The reactive gas releasing compounds shown above can release CO₂ during irradiation of the underlayer-coated substrates with radiation, such as UV, EUV, ion-beams, and the like. During irradiation of metal oxide resist materials, such as organotin materials, reactive sites are generated that can react with CO₂ to form metal carbonate bonds that can drive improved solubility contrast between the irradiated and non-irradiated areas of the photoresist. Alternatively, or additionally, the reactive gas releasing compound can release CO₂ during a heating step, such as during a post-apply bake (PAB) or post-exposure bake (PEB). CO₂ released during a hearing step can similarly react with the organotin materials.

Polymer and/or Polymer-Forming Compositions for Underlayer

The polymer and/or polymer-forming composition for the underlayer (referred to herein as Polymer B) can generally comprise polymers, oligomers, and/or small-molecule compositions that are capable of forming film compositions comprising polymeric structures having one or more desirable structural units. In some embodiments, Polymer (B) may be a polycondensation compound, a compound obtained by a reaction other than polycondensation, and/or the like.

While generally, the function of the polymer to form a supportive matrix for the reactive gas releasing compound (A) can be any of a wide range of polymers, it can be desirable to draw on existing underlayer compositions that have a track record of use in photolithography. Ultimately the underlayers are generally removed at later stages of the processing, so known polymer materials have established suitability for the process environment and overall process flow.

Polymer (B) is exemplified herein as a polymeric composition having at least two structural units, having a side chain and a main chain. The “main chain” as referred to herein means a longest chain among chains constituted from atoms in the polymer. The “side chain” as referred to herein means a chain other than the longest chain, among the chains constituted from the atoms in the polymer.

### Polymer Structural Components

Polymer (B) provides a matrix for the reactive gas releasing species as well as generally providing stabilization and improved adhesion for the organometallic resist. The selection of the suitable polymer can be guides by these properties as well as having suitable processing for the radiation patterning equipment and process environment. From that perspective, it can be useful to adapt polymers that have established uses in the photolithography arts. In this context, several classes of polymers are described below.

In some embodiments, the polymer (B) can comprise structural units having an aromatic ring. In some embodiments, the structural units having an aromatic ring can be substituted with fluorine. Suitable structural units having aromatic ring structures include aromatic carbon rings (e.g., a benzene ring, a naphthalene ring, an anthracene ring, an indene ring, a pyrene ring, a fluorenylidenebiphenyl ring, a fluorenylidenebinaphthalene ring, and the like), aromatic heterocycles (e.g., a furan ring, a pyrrole ring, a thiophene ring, a phosphole ring, a pyrazole ring, an oxazole ring, an isoxazole ring, a thiazole ring, a pyridine ring, a pyrazine ring, a pyrimidine ring, a pyridazine ring, a triazine ring, and the like), and the like. In some embodiments, polymer (B) comprises aromatic carbon rings.

Some suitable examples of structural units comprising compositions having aromatic ring structures include novolac resins, resol resins, styrene resins, acenaphthylene resins, indene resins, arylene resins, calixarene resins, and the like.

Suitable examples of novolac resins are resins obtained by allowing a phenolic compound to react with an aldehyde compound, a divinyl compound, or the like using an acidic catalyst. A plurality of phenolic compounds may be mixed with an aldehyde compound, a divinyl compound, or the like and allowed to react. Some suitable examples of phenolic compounds include phenols (e.g., phenol, cresol, xylenol, resorcinol, bisphenol A, p-tert-butylphenol, p-octylphenol, 9,9-bis(4-hydroxyphenyl)fluorene, 9,9-bis(3-hydroxyphenyl)fluorene, and 4,4′-(α-methylbenzylidene)bisphenol), naphthols (e.g., α-naphthol, β-naphthol, 1,5-dihydroxynaphthalene, 2,7-dihydroxynaphthalene, and 9,9-bis(6-hydroxynaphthyl)fluorene), anthrols (e.g., 9-anthrol), pyrenols (e.g., 1-hydroxypyrene and 2-hydroxypyrene), and the like.

Some suitable examples of aldehyde compounds for reacting with phenolic compounds include aldehydes (e.g., formaldehyde, benzaldehyde, 1-naphthaldehyde, 2-naphthaldehyde, and 1-formylpyrene), aldehyde sources (e.g., paraformaldehyde and trioxane), and the like.

Some suitable examples of divinyl compounds for reacting with phenolic compounds include divinylbenzene, dicyclopentadiene, tetrahydroindene, 4-vinylcyclohexene, 5-vinylnorborna-2-ene, divinylpyrene, limonene, 5-vinylnorbornadiene, and the like.

Some suitable examples of novolac resins include 1) resins having a structural unit derived from phenol and formaldehyde, 2) resins having a structural unit derived from cresol and formaldehyde, 3) resins having a structural unit derived from dihydroxynaphthalene and formaldehyde, 4) resins having a structural unit derived from fluorene bisphenol and formaldehyde, 5) resin having a structural unit derived from fluorene bisnaphthol and formaldehyde, 6) resins having a structural unit derived from hydroxypyrene and formaldehyde, 7) resins having a structural unit derived from hydroxypyrene and naphthaldehyde, 8) resins having a structural unit derived from 4,4′-(α-methylbenzylidene) bisphenol and formaldehyde, 9) resins having a structural unit derived from a phenol compound and formylpyrene, 10) resins being a combination thereof, and 11) resins obtained by substituting a part or all of hydrogen atoms of the phenolic hydroxyl groups of any of these resins with a propargyl group or the like, and 12) like resins.

Suitable examples of a resol resin are resins obtained by allowing a phenolic compound to react with an aldehyde compound using an alkaline catalyst.

Suitable examples of styrene resins are resins having a structural unit derived from a compound containing an aromatic ring and a polymerizable carbon-carbon double bond. Aside from the aforementioned structural units, the styrene resin may have a structural unit derived from an acrylic monomer, a vinyl ether, or the like.

Some suitable examples of styrene resins include polystyrene, polyvinylnaphthalene, polyhydroxystyrene, polyphenyl (meth)acrylate, a resin being a combination thereof, and the like.

Suitable examples of an acenaphthylene resin are resins having a structural unit derived from a compound that includes an acenaphthylene skeleton. Some examples of an acenaphthylene resin include a copolymer of acenaphthylene and hydroxymethylacenaphthylene, and the like.

Suitable examples of indene resins are resins having a structural unit derived from a compound that includes an indene skeleton.

Suitable examples of arylene resins are resins having a structural unit derived from a compound that includes an arylene skeleton. The arylene skeleton is exemplified by a phenylene skeleton, a naphthylene skeleton, a biphenylene skeleton, and the like. Some suitable examples of an arylene resin include polyarylene ether, polyarylene sulfide, polyarylene ether sulfone, polyarylene ether ketone, a resin having a structural unit that includes a biphenylene skeleton, a resin having a structural that includes a biphenylene skeleton and a structural unit derived from a compound that includes an acenaphthylene skeleton, and the like.

Suitable examples of triazene resins are resins having a structural unit derived from a compound that includes a triazene skeleton, such as a melamine compound, a cyanuric acid compound, and the like.

In some embodiments, polymer (B) can comprise one or more fluorine-containing structural units, such as those described in the '267 application. For example, suitable fluorine-containing structural units can be represented by the following formula (1), where the repeating unit in parentheses repeat to provide the appropriate molecular weight or distribution thereof:

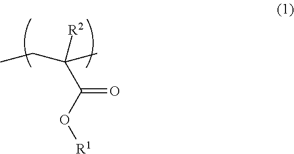

In the above formula (1), R¹ represents a fluorine atom-containing monovalent organic group having 1 to 20 carbon atoms, and R² represents a hydrogen atom or a monovalent hydrocarbon group having 1 to 20 carbon atoms. An appropriate copolymer can comprise non-fluorine containing structural units (2), which can have a formula equivalent to (1) except without the fluorine substituents.

The “organic group” as referred to herein means a group that includes at least one carbon atom, and this discussion applies to any suitable organic group herein unless specifically indicated otherwise. Suitable examples of monovalent organic groups can comprise monovalent linear or branched hydrocarbon groups having 1 to 20 carbon atoms, such as alkyl groups (e.g., methyl, ethyl, propyl, butyl, pentyl, hexyl, their isomers, and the like), alkenyl groups (e.g., ethenyl, propenyl, butenyl, their isomers, and the like), alkynyl groups (e.g., ethynyl, propynyl, butynyl, and the like), alicyclic groups, such as cycloalkyl groups (e.g., cyclopentyl, cyclohexyl, and the like), cycloalkenyl groups (e.g., cyclopropenyl, cyclopentenyl, cyclohexenyl, and the like), bridged cyclic groups (e.g., norbornyl, adamantly, and the like), and aromatic groups, such as aryl groups (e.g., phenyl, tolyl, xylyl, napthyl, and the like) and aralkyl groups (e.g., benzyl, phenethyl, napthylmethyl, and the like).

In some embodiments, the organic group, such as the R¹ group, can comprise divalent heteroatom groups, such as —CO—, —CS—, —NH—, —O—, —S—, and/or combination thereof, and the like, wherein the divalent heteroatom group is bound between two adjacent carbon atoms of the monovalent hydrocarbon group having 1 to 20 carbon atoms. In some embodiments, the organic group can comprise monovalent heteroatom groups, such as a hydroxyl group, a sulfanyl group, a cyano group, a nitro group, a primary amine, a halogen atom, and the like. Tertiary amine substituents are also possible.

The fluorine atom-containing monovalent organic group having 1 to 20 carbon atoms represented by R¹ is exemplified by a group obtained by substituting one or more hydrogens of the monovalent organic groups as defined above with a fluorine atom.

Some suitable examples of fluorine atom-containing monovalent organic groups having 1 to 20 carbon atoms include fluorinated hydrocarbon groups such as fluorinated chain hydrocarbon groups (e.g., fluorinated alkyl groups such as a trifluoromethyl group, a 2,2,2-trifluoroethyl group, a pentafluoroethyl group, a 2,2,3,3,3-pentafluoropropan-1-yl group, a 1,1,1,3,3,3-hexafluoropropan-2-yl group, a heptafluoropropan-1-yl group, a 2,2,3,3,4,4,4-heptafluorobutan-1-yl group, a nonafluorobutan-1-yl group, a 3,3,4,4,5,5,6,6,6-nonafluorohexan-1-yl group, and a tridecafluorohexan-1-yl group), fluorinated alicyclic hydrocarbon groups (e.g., fluorinated cycloalkyl groups such as an undecafluorocyclohexan-1-yl group and an undecafluorocyclohexan-1-yl methyl group), and fluorinated aromatic hydrocarbon groups (e.g., fluorinated aryl groups such as a 2,4,6-trifluorophenyl group and a pentafluorophenyl group, and fluorinated aralkyl groups such as a pentafluorobenzyl group).

Further suitable examples of fluorine atom-containing monovalent organic groups having 1 to 2 carbon atoms include groups containing an oxygen atom and a fluorine atom such as a group containing an oxo group and a fluorine atom (e.g., a 4,4,4-trifluoro-3-oxobutan-1-yl group), a group containing an ether group and a fluorine atom (e.g., a 4,4,5,5,6,6,6-heptafluoro-3-oxahexan-1-yl group), a group containing a hydroxy group and a fluorine atom (e.g., a 2-hydroxy-2-trifluoromethyl-3,3,3-trifluoropropan-1-yl group, a 4-hydroxy-4-trifluoromethyl-5,5,5-trifluoropentan-2-yl group, and a 3,5-di(1-hydroxy-1-trifluoromethyl-2,2,2-trifluoroethyl)cyclohexan-1-yl group), and the like.

In some embodiments, R¹ comprises a fluorinated hydrocarbon group, in some embodiments R¹ comprises a fluorinated chain hydrocarbon group, in other embodiments R¹ comprises a fluorinated alkyl group, and in further embodiments R¹ comprises a 2,2,2-trifluoroethyl group or a 1,1,1,3,3,3-hexafluoropropan-2-yl group.

In Formula (1) above, R² can generally comprise monovalent hydrocarbon groups having 1 to 20 carbon atoms as described above. In some embodiments, R² can comprise a hydrogen atom or a chain hydrocarbyl group, in other embodiments, R² can comprise a hydrogen atom or an alkyl group, and in other embodiments R² can comprise a hydrogen atom or a methyl group. R² can further comprise heteroatoms, as indicated above in the context of general organic groups.

In some embodiments, the proportion of the structural unit (1) contained with respect to total structural units constituting the polymer (B) can be from about 1 mol % to about 100 mol %, from about 10 mol % to about 90 mol % in other embodiments, from about 20 mol % to about 80 mol % in other embodiments, and from about 40 mol % to about 75 mol % in further embodiments. The remaining repeat units of polymer (B) may be structural units (2). A person of ordinary skill in the art will recognize that additional ranges within the explicit ranges above are contemplated and are within the present disclosure.

In some embodiments, polymer (B) can comprise one or more silicon-containing compounds, such as a polysiloxane. Some suitable examples of silicon-containing compounds are described in the '575 application referenced above. Suitable silicon-containing compounds can be generally represented by the formula (HₐR_{b}SiO_{(4-a-b)/2)}, wherein a=0, 1, 2, or 3, b=0, 1, 2, or 3, and R is a monovalent organic group having 1 to 20 carbon atoms, a hydroxyl group, or a halogen atom, and wherein in the case where b=2 or 3, R can be the same or different. These moieties can be organized into the polymer to form a —Si—O— repeat units along the polymer chain and may form a polysiloxane. Some suitable examples of monovalent organic groups can comprise monovalent linear or branched hydrocarbon groups having 1 to 20 carbon atoms, such as alkyl groups (e.g., methyl, ethyl, propyl, butyl, pentyl, hexyl, their isomers, and the like), alkenyl groups (e.g., ethenyl, propenyl, butenyl, their isomers, and the like), alkynyl groups (e.g., ethynyl, propynyl, butynyl, and the like), alicyclic groups, such as cycloalkyl groups (e.g., cyclopentyl, cyclohexyl, and the like), cycloalkenyl groups (e.g., cyclopropenyl, cyclopentenyl, cyclohexenyl, and the like), bridged cyclic groups (e.g., norbornyl, adamantly, and the like), and aromatic groups, such as aryl groups (e.g., phenyl, tolyl, xylyl, napthyl, and the like) and aralkyl groups (e.g., benzyl, phenethyl, napthylmethyl, and the like).

In embodiments wherein polymer (B) comprises one or more silicon-containing moieties, it can be desirable for the silicon-containing groups of the polymer to comprise an Si—H bond, such as those where a=1 in the formula above and represented by the following formula:

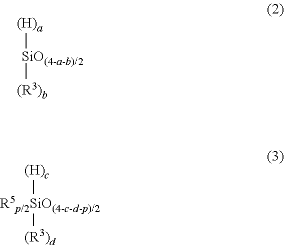

In the above formula (2) and (3), “a” is an integer of 1 to 3; R³ represents a hydroxy group, a halogen atom, or a monovalent organic group having 1 to 20 carbon atoms; and b is an integer of 0 to 2, wherein in a case in which b is 2, two R³s are identical or different, and wherein a sum of “a” and b is no greater than 3. As suggested above, these moieties are found in the polymers with a double bonded oxygen becoming an —Si—O— linkage (polysiloxane) along the polymer backbone.

In the above formula (1-2), c is an integer of 1 to 3; R⁴ represents a hydroxy group, a halogen atom, or a monovalent organic group having 1 to 20 carbon atoms; d is an integer of 0 to 2, wherein in a case in which d is 2, two R²s are identical or different; R⁵ represents a substituted or unsubstituted divalent hydrocarbon group having 1 to 20 carbon atoms that bonds to two Si atoms; and p is an integer of 1 to 3, wherein in a case in which p is no less than 2, a plurality of R⁵s are identical or different, and wherein a sum of c, d, and p is no greater than 4.

The monovalent organic group having 1 to 20 carbon atoms which may be represented by R³ or R⁴ is exemplified by: a monovalent hydrocarbon group having 1 to 20 carbon atoms; a monovalent group having 1 to 20 carbon atoms that contains a divalent hetero atom-containing group between two adjacent carbon atoms of the monovalent hydrocarbon group; a monovalent group having 1 to 20 carbon atoms obtained by substituting with a monovalent hetero atom-containing group, a part or all of hydrogen atoms included in the monovalent hydrocarbon group or the group that contains a divalent hetero atom-containing group; a monovalent group containing —O— in combination with the monovalent hydrocarbon group having 1 to 20 carbon atoms, the monovalent group having 1 to 20 carbon atoms that contains a divalent hetero atom-containing group between two adjacent carbon atoms of the monovalent hydrocarbon group, or the monovalent group having 1 to 20 carbon atoms obtained by substituting with a monovalent hetero atom-containing group, a part or all of hydrogen atoms included in the monovalent hydrocarbon group or the group that contains a divalent hetero atom-containing group; and the like.

Exemplary monovalent hydrocarbon groups containing 1 to 20 carbon atoms include a monovalent chain hydrocarbon group having 1 to 20 carbon atoms, a monovalent alicyclic hydrocarbon group having 3 to 20 carbon atoms, and a monovalent aromatic hydrocarbon group having 6 to 20 carbon atoms.

Examples of the monovalent chain hydrocarbon group having 1 to 20 carbon atoms include: alkyl groups such as a methyl group and an ethyl group; alkenyl groups such as an ethenyl group; alkynyl groups such as an ethynyl group; and the like.

Examples of the monovalent alicyclic hydrocarbon group having 3 to 20 carbon atoms include: monovalent monocyclic alicyclic saturated hydrocarbon groups such as a cyclopentyl group and a cyclohexyl group; monovalent monocyclic alicyclic unsaturated hydrocarbon groups such as a cyclopentenyl group and a cyclohexenyl group; monovalent polycyclic alicyclic saturated hydrocarbon groups such as a norbornyl group and an adamantyl group; monovalent polycyclic alicyclic unsaturated hydrocarbon groups such as a norbornenyl group and a tricyclodecenyl group; and the like.

Examples of the monovalent aromatic hydrocarbon group having 6 to 20 carbon atoms include: aryl groups such as a phenyl group, a tolyl group, a xylyl group, a naphthyl group, a methylnapthyl group, and an anthryl group; aralkyl groups such as a benzyl group, a napthylmethyl group, and an anthrylmethyl group; and the like.

The hetero atom constituting the divalent hetero atom-containing group and the monovalent atom-containing group is exemplified by an oxygen atom, a nitrogen atom, a sulfur atom, a phosphorus atom, a silicon atom, a halogen atom, and the like. Examples of the halogen atom include a fluorine atom, a chlorine atom, a bromine atom, an iodine atom, and the like.

Examples of the divalent hetero atom-containing group include —O—, —CO—, —S—, —CS—, —NR′—, and combinations thereof and the like, wherein R′ represents a hydrogen atom or a monovalent hydrocarbon group. In some embodiments, the divalent hetero atom-containing group is —O—, and in other embodiments, the divalent hetero atom-containing group is —S—.

Examples of the monovalent hetero atom-containing group include a halogen atom, a hydroxy group, a carboxy group, a cyano group, an amino group, a sulfanyl group, and the like.

In some embodiments, the monovalent organic group represented by R³ or R⁴ has from about 1 to 10 carbon atoms, and from about 1 to 6 carbon atoms in further embodiments.

In some embodiments, R³ or R⁴ comprises a chlorine atom.

In some embodiments, R³ and R⁴ represent a monovalent chain hydrocarbon group, a monovalent aromatic hydrocarbon group, or a monovalent group obtained by substituting with a monovalent hetero atom-containing group, a part or all of hydrogen atoms included in the monovalent hydrocarbon group. In some embodiments, R³ and R⁴ are independently an alkyl group or an aryl group, in other embodiments R³ and R⁴ are independently a methyl group, an ethyl group, or a phenyl group, and in further embodiments R³ and R⁴ are independently a methyl group or an ethyl group.

In some embodiments, R⁵ is a substituted or unsubstituted divalent hydrocarbon group having 1 to 20 carbon atoms that bonds to two Si atoms. In some embodiments, R⁵ is a substituted or unsubstituted divalent aliphatic cyclic hydrocarbon group having 3 to 20 carbon atoms, a substituted or unsubstituted divalent aromatic hydrocarbon group having 6 to 20 carbon atoms, and the like.

Some suitable examples of the unsubstituted divalent chain hydrocarbon group having 1 to 20 carbon atoms include: chain saturated hydrocarbon groups such as a methanediyl group and an ethanediyl group; chain unsaturated hydrocarbon groups such as an ethenediyl group and a propenediyl group; and the like.

Examples of the unsubstituted divalent aliphatic cyclic hydrocarbon group having 3 to 20 carbon atoms include: monocyclic saturated hydrocarbon groups such as a cyclobutanediyl group; monocyclic unsaturated hydrocarbon groups such as a cyclobutenediyl group; polycyclic saturated hydrocarbon groups such as a bicyclo[2.2.1]heptanediyl group; polycyclic unsaturated hydrocarbon groups such as a bicyclo[2.2.1]heptenediyl group; and the like.

Examples of the unsubstituted divalent aromatic hydrocarbon group having 6 to 20 carbon atoms include a phenylene group, a biphenylene group, a phenyleneethylene group, a napthylene group, and the like.

Examples of a substituent in the substituted divalent hydrocarbon group having 1 to 20 carbon atoms represented by R⁵ include a halogen atom, a hydroxy group, a cyano group, a nitro group, an alkoxy group, an acyl group, an acyloxy group, and the like.

In some embodiments, R⁵ is an unsubstituted chain saturated hydrocarbon group or an unsubstituted aromatic hydrocarbon group. In other embodiments R⁵ is a methanediyl group, an ethanediyl group, or a phenylene group.

In some embodiments, “a” is 1 or 2, and in specific embodiments, “a” is 1.

In some embodiments, “b” is 0 or 1, and in specific embodiments, “b” is 0.

In some embodiments, “c” is 1 or 2, and in specific embodiments, “c” is 1.

In some embodiments, “d” is 0 or 1, and in specific embodiments, “d” is 0.

In some embodiments, “p” is 2 or 3.

In embodiments wherein polymer (B) comprises one or more silicon-containing compounds, the silicon-containing compounds can comprise from at about 1% by mass to about 99% by mass, from about 5% by mass to about 75% by mass in some embodiments, and from about 10% by mass to about 50% by mass in further embodiments. A person of ordinary skill in the art will recognize that additional ranges within the explicit ranges above are contemplated and are within the present disclosure.

The synthesis of a polymer (B) based on a copolymer of moieties shown in equations (2) and (3) above are presented in the examples below. Further examples are described in the '247 application cited above. In the synthesis of these polymers, orthoesters are used as water scavengers to resist hydrolyzing of the polymer or precursors thereof that would result in gelation and modification of the materials. These orthoesters are generally removed with the solvent during solvent removal. These polymers (B) are used in the examples in combination with CO₂ releasing agents. Orthoesters are also described herein as alcohol releasing agents, which release alcohols in response to water released from corresponding water releasing agents. While based on the same chemical reactivities of the orthoesters, these are distinct applications of the compounds.

The polymer (B) can also comprise one or more structural units represented by the following Formulae (4) and/or (5).

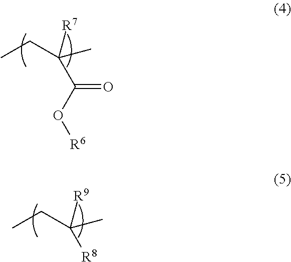

In the above formulae (4) and (5), R⁶ and R⁸ independently comprise a monovalent hydrocarbon group having 1 to 20 carbon atoms, and R⁷ and R⁹ independently comprise a hydrogen atom or a monovalent hydrocarbon group having 1 to 20 carbon atoms. Suitable examples of monovalent hydrocarbon groups having 1 to 20 carbon atoms are similar to those exemplified above as the monovalent hydrocarbon group having 1 to 20 carbon atoms in Formula 1. Some suitable examples of monovalent organic groups can comprise monovalent linear or branched hydrocarbon groups having 1 to 20 carbon atoms, such as alkyl groups (e.g., methyl, ethyl, propyl, butyl, pentyl, hexyl, their isomers, and the like), alkenyl groups (e.g., ethenyl, propenyl, butenyl, their isomers, and the like), alkynyl groups (e.g., ethynyl, propynyl, butynyl, and the like), alicyclic groups, such as cycloalkyl groups (e.g., cyclopentyl, cyclohexyl, and the like), cycloalkenyl groups (e.g., cyclopropenyl, cyclopentenyl, cyclohexenyl, and the like), bridged cyclic groups (e.g., norbornyl, adamantly, and the like), and aromatic groups, such as aryl groups (e.g., phenyl, tolyl, xylyl, napthyl, and the like) and aralkyl groups (e.g., benzyl, phenethyl, napthylmethyl, and the like).

In some embodiments, R⁶ and R⁸ independently comprise a chain hydrocarbon group, in some embodiments R⁶ and R⁸ independently comprise an alkyl group, and in other embodiments R⁶ and R⁸ independently comprise a butan-1-yl group or a 2-ethylhexan-1-yl group.

In some embodiments, the proportion of the structural units (4) and (5) Individually contained with respect to total structural units constituting the polymer (B) can be from about 1 mol % to about 100 mol %, in other embodiments from about 5 mol % to about 90 mol %, in other embodiments from about 10 mol % to about 75 mol %, and in further embodiments from about 20 mol % to about 60 mol %. A person of ordinary skill in the art will recognize that additional ranges within the explicit ranges above are contemplated and are within the present disclosure.

In some embodiments, the polymer (B), such as polymers based on formulae (1), (4) and (5), may comprise other structural units. Some examples of such suitable other structural units can comprise structural units derived from a (meth)acrylic acid, an acenaphthylene compound, and the like. In embodiments in which polymer (B) comprises other structural unit(s), the upper limit of a proportion of the other structural unit(s) contained with respect to total structural units constituting the polymer (B) can be from 0 mol % to about 20 mol %, from about 1 mol % to about 15 mol % in other embodiments, and from about 5 mol % to about 10 mol % in further embodiments. In some embodiments, the proportion of the other structural unit(s) contained in the polymer (B) may be 0 mol %. A person of ordinary skill in the art will recognize that additional ranges within the explicit ranges above are contemplated and are within the present disclosure.

In some embodiments, the weight average molecular weight (Mw) of the polymer (B) can be from about 1,000 to about 100,000, from about 2,000 to about 50,000 in some embodiments, from about 3,000 to about 30,000 in some embodiments, and from about 4,000 to about 20,000 in further embodiments. A person of ordinary skill in the art will recognize that additional ranges within the explicit ranges above are contemplated and are within the present disclosure.

In embodiments wherein the polymer (B) being a novolac resin, a resol resin, a styrene resin, an acenaphthylene resin, an indene resin, an arylene resin, or a triazene resin, the polystyrene-equivalent weight average molecular weight (Mw) of the polymer (B) can be determined by gel permeation chromatography (GPC). In some embodiments, Mw can be from about 1,000 to about 100,000, from about 2,000 to about 60,000 in other embodiments, from about 3,000 to about 30,000 in further embodiments, and from about 4,000 to about 15,000 in still further embodiments. A person of ordinary skill in the art will recognize that additional ranges within the explicit ranges above are contemplated and are within the present disclosure.

In some embodiments, Mw/Mn (“Mn” as referred to herein means a polystyrene-equivalent number average molecular weight as determined by GPC) of polymer B can be from about 1 to about 5, from about 1.1 to about 3 in some embodiments, and from about 1.2 to about 2 in other embodiments. A person of ordinary skill in the art will recognize that additional ranges within the explicit ranges above are contemplated and are within the present disclosure.

As referred to herein, the Mw and the Mn of the polymer are values measured by gel permeation chromatography employing a differential refractometer detector using GPC columns (“G2000 HXL”×2, “G3000 HXL”×1, and “G4000 HXL”×1, available commercially, for example, from Tosoh Corporation) under an analytical conditions involving a flow rate of 1.0 mL/min, an elution solvent of tetrahydrofuran, and a column temperature of 400° C., with mono-dispersed polystyrene as a standard.

Suitable examples of calixarene resins are cyclic oligomers derived from a plurality of aromatic rings to which a hydroxy group bonds, through linking to be cyclic via a hydrocarbon group, or the cyclic oligomer from which a part or all of hydrogen atoms included in the hydroxy group, the aromatic ring, and the hydrocarbon group are substituted.

Further examples of suitable calixarene resins include cyclic tetramers to dodecamers formed from formaldehyde and a phenol compound (e.g., phenol or naphthol), cyclic tetramers to dodecamers formed from a benzaldehyde compound and a phenol compound (e.g., phenol or naphthol), substituted resins obtained by substituting a hydrogen atom of the phenolic hydroxyl groups contained in these cyclic compounds with a propargyl group or the like, and the like.

In some embodiments, the molecular weight of the calixarene resin can be from about 500 to about 5,000, from about 700 to about 3,000 in other embodiments, and from about 1,000 to about 1,500 in further embodiments. A person of ordinary skill in the art will recognize that additional ranges within the explicit ranges above are contemplated and are within the present disclosure.

In some embodiments, the proportion of polymer (B) with respect to total components other than the organic solvent (C) in the composition for forming a resist underlayer film is from about 1% by mass to about 70% by mass, from about 3% by mass to about 65% by mass in other embodiments, from about 5% by mass to about 60% by mass in other embodiments, from about 10% by mass to about 55% by mass in other embodiments, from about 15% by mass to about 50% by mass in other embodiments, and from about 20% by mass to about 40% by mass in further embodiments. A person of ordinary skill in the art will recognize that additional ranges within the explicit ranges above are contemplated and are within the present disclosure.

In some embodiments, the proportion of polymer (B) in the composition for forming a resist underlayer film is from about 0.01% by mass to about 50% by mass, from about 0.1% by mass to about 20% by mass in other embodiments, and from about 1% by mass to about 10% by mass in further embodiments. A person of ordinary skill in the art will recognize that additional ranges within the explicit ranges above are contemplated and are within the present disclosure.

### Solvent

The organic solvent is not particularly limited insofar as it is capable of effectively dissolving or dispersing the reactive gas releasing compound (A), polymer (B), and additional optional components. Suitable examples of organic solvents are alcohols, ketones, ethers, esters, nitrogen-containing solvents, hydrocarbons, combinations thereof, and the like. In some embodiments, the organic solvent (C) may comprise one or more solvent types.

Suitable examples of alcohol solvents include monohydric alcohols such as methanol, ethanol, n-propanol, iso-propanol, butanol, iso-butanol and the like, and polyhydric alcohols such as ethylene glycol, 1,2-propylene glycol, and the like. Suitable examples of ketone solvents include chain ketones such as methyl ethyl ketone, methyl isobutyl ketone, and the like, and cyclic ketones such as cyclohexanone and the like.

Suitable examples of ether solvents include polyhydric alcohol ether solvents, (e.g., chain ether solvents such as n-butyl ether), cyclic ether solvents (e.g., tetrahydrofuran, 1,4-dioxane, and the like), polyhydric alcohol partial ether solvents (e.g., diethylene glycol monomethyl ether), and the like.

Suitable examples of ester solvents include carbonate solvents (e.g., dimethyl carbonate, diethyl carbonate, and the like), acetic acid monoester solvents (e.g., methyl acetate, ethyl acetate, and the like), lactone solvents (e.g., γ-butyrolactone and the like), polyhydric alcohol partial ether carboxylate solvents (e.g., diethylene glycol monomethyl ether acetate, propylene glycol monomethyl ether acetate, and the like), lactic acid ester solvents (e.g., methyl lactate, ethyl lactate, and the like), and the like.

Suitable examples of nitrogen-containing solvents include chain nitrogen-containing solvents (e.g., N,N-dimethylacetamide and the like), cyclic nitrogen-containing solvents (e.g., N-methylpyrrolidone and the like), and the like.

Suitable examples of hydrocarbon solvents include aliphatic hydrocarbon solvents (e.g., decalin and the like), aromatic hydrocarbon solvents (e.g., toluene, xylenes, and the like), and the like.

In some embodiments, the organic solvent (C) can comprise from about 50% by mass to about 99.9% by mass of the total composition for forming a resist underlayer film, from about 60% by mass to about 99% by mass of the total composition in other embodiments, and from about 70% by mass to about 95% by mass of the total composition in further embodiments. A person of ordinary skill in the art will recognize that additional ranges within the explicit ranges above are contemplated and are within the present disclosure.

### Optional Components

The composition for forming a resist underlayer may further include optional components (D), such as acid generating agents, such as photo-acid generators, orthoesters, additives, such as surfactants, adhesion promoters, and the like, or combinations thereof.

### Acid Generating Agent

The acid generating agent is a component capable of generating an acid upon exposure to radiation or heating. Examples of the acid generating agent capable of generating an acid upon exposure to radiation (hereinafter, may be also referred to as “photo acid generating agent” or a photoacid generator (PAG)) include acid generating agents disclosed in paragraphs [0077] to [0081] of Japanese Patent Application, Publication No. 2004-168748, incorporated herein by reference, as well as triphenylsulfonium, trifluoromethanesulfonate and the like. Triphenylsulfonium is an example of an onium ion, which may release acid in response to acid or heat. As described above, for certain reactive gas releasing agents, an acid generating agent can react with and/or activate the reactive gas releasing compound to trigger the release of the reactive gas. For these embodiments, the acid generating agent is also an activating additive. The acid generating additive can be useful for other purposes also in the underlayer.

Examples of the acid generating agent capable of generating an acid upon heating (hereinafter, may be also referred to as “thermal acid generating agent” or a thermal acid generator (TAG)) include onium salt-type acid generating agents exemplified as the photo acid generating agent in the above-mentioned patent document, as well as 2,4,4,6-tetrabromocyclohexadienone, benzoin tosylate, 2-nitrobenzyl tosylate, alkyl sulfonates, and the like. Some of the reactive gas releasing agents described above comprise onium salts, which serve then a dual function as counter ions for reactive gas releasing agents as well as acid generators. Acid generating moieties can also be covalently bonded to the matrix polymer at a side chain, such as sulfonium sulfonates, iodonium sulfonates, N-sulfonic imides, and N-sulfonic imines. Polymers with covalently bound photoacid generators are described further in published U.S. patent application 2021/011383 to Cardineau et al., entitled “Stabilizing Interfaces of Inorganic Radiation Patterning Compositions on Substrates,” incorporated herein by reference.

In the case in which the composition contains the acid generating agent, the upper limit of a content of the acid generating agent with respect to 100 parts by mass of the compound (B) is no more than 100 parts by mass, in some embodiment no more than 40 parts by mass, in further embodiments no more than 30 parts by mass, and in other embodiments from about 0.5 parts by mass to about 25 parts per mass. A person of ordinary skill in the art will recognize that additional ranges of acid generating agent within the explicit ranges above are contemplated and are within the present disclosure.

### Orthoester

In some embodiments, it can be desirable for the film-forming composition to comprise an orthoester. In some embodiments, the film-forming composition can comprise an orthoester and a polymer-forming composition that comprises a silicon-containing compound, such as those described above. For the processing of these silicon-containing polymers, the orthoesters can function as a water sequestering agent to inhibit hydrolysis of the polymer, which can be undesirable. As a processing aid, the orthoesters are generally provided in large concentrations, and they are removed with the solvent during solvent removal. The use of orthoesters in polymer underlays for the processing of organic photoresists is described in the '575 application cited above. The presence of the orthoesters are found to improve pattern formation and/or vapor development relative to the use of the underlayers without the orthoesters. The orthoester is generally an ester of an orthocarboxylic acid. While not wanting to be limited by theory, the orthoester is believed to drive reaction with water to give a carboxylic acid ester or the like. Examples of the orthoester include: orthoformic acid esters such as methyl orthoformate, ethyl orthoformate, and propyl orthoformate; orthoacetic acid esters such as methyl orthoacetate, ethyl orthoacetate, and propyl orthoacetate; orthopropionic acid esters such as methyl orthopropionate, ethyl orthopropionate, and propyl orthopropionate; and the like. In some embodiments, the orthoester is an orthoformic acid ester. In some embodiments, the orthoester is trimethyl orthoformate.

While the orthoesters are generally removed during processing of the exemplified silico-containing polymers, they can be incorporated into polymers along with water releasing agent, such as those described above, to transform a water releasing underlayer into an alcohol releasing underlayer along with a polymer that is appropriately resistant to water driven degradation In these embodiments, the orthoester can be considered a reactive gas releasing agent in the context of an alcohol reactive gas. Suitable acrylate based polymers are described above.

In the case in which the composition contains the orthoester as a dehydrating agent for aiding the processing of the silicon-based polymer, the lower limit of a content of the orthoester with respect to 100 parts by mass of the compound (B) can be about 10 parts by mass, in some embodiments about 100 parts by mass, in further embodiments about 200 parts by mass, and in some embodiments about 300 parts by mass. The upper limit of the orthoester content relative to 100 parts by mass of compound (B) can be about 10,000 parts by mass, in some embodiments about 5,000 parts by mass, in further embodiments about 2,000 parts by mass, and in other embodiments about 1,000 parts by mass. When used as an alcohol releasing agent in combination with a water releasing agent, the amount of orthoester can be referenced relative to mole equivalents of water releasing agents. The amounts can depend on whether or not it is desired to try to convert most or effectively all released water into alcohol, or only converting a fraction of the released water In some embodiments, the amount of orthoester can be at least about 1 mole percent relative to the mole equivalent amount of (A), in further embodiments with ranges with a lower limit of about 10 mole %, about 25 mole %, about 50 mole %, about 75 mole %, about 100 mole % or about 120 mole %, along with an upper limit for any lower limit of about 5000 mole %, about 1000 mole %, about 500 mole %, about 250 mole % or about 200 mole %. A person of ordinary skill in the art will understand that additional ranges of orthoester within the explicit ranges above are contemplated and are within the present disclosure.

### Optional Additives

The underlayer film forming composition can further comprise other additives, which are generally present each in amounts of no more than 10 weight percent and in further embodiments no more than about 5 weight percent. A person of ordinary skill in the art will recognize that additional ranges of additive amounts within the explicit ranges are contemplated and are within the present disclosure. Suitable additives can include, for example, viscosity modifiers, crosslinking agents, polymerization catalysts, wetting agents, surfactants, adhesion promoters, other property modifiers, and combinations thereof.

### Formation of Underlayer Coating

The composition for forming a resist underlayer film may be prepared, for example, by mixing appropriate ratios of the reactive gas releasing compound (A), the polymer (B), and the organic solvent (C), as well as any optional component(s). The compositions for forming resist underlayer films described herein can be further processed by any suitable means known in the art, such filtration, to afford high-purity compositions for forming resist underlayers.

Underlayers films can be formed from the underlayer film-forming compositions described herein by processing of the underlayer film-forming compositions onto a selected substrate. A substrate generally presents a surface onto which the coating material can be deposited, and the substrate may comprise a plurality of layers in which the surface relates to an upper most layer. In some embodiments, the substrate surface can be treated to prepare the surface for adhesion of the coating material. Also, the surface can be cleaned and/or smoothed as appropriate. Suitable substrate surfaces can comprise any reasonable material. Some substrates of particular interest include, for example, silicon wafers, silica substrates, other inorganic materials such as ceramic materials, polymer substrates, such as organic polymers, composites thereof and combinations thereof across a surface and/or in layers of the substrate. Wafers, such as relatively thin cylindrical structures, can be convenient, although any reasonable shaped structure can be used. Polymer substrates or substrates with polymer layers on non-polymer structures can be desirable for certain applications based on their low cost and flexibility, and suitable polymers can be selected based on the relatively low processing temperatures that can be used for the processing of the patternable materials described herein. Suitable polymers can include, for example, polycarbonates, polyimides, polyesters, polyalkenes, copolymers thereof and mixtures thereof. In general, it is desirable for the substrate to have a flat surface, especially for high resolution applications.

In general, any suitable solution coating process can be used to deliver the underlayer-forming composition to a substrate. Suitable coating approaches can include, for example, spin coating, spray coating, dip coating, knife edge coating, printing approaches, such as inkjet printing and screen printing, and the like. In some embodiments, spin coating is used to deliver the underlayer-forming composition to a substrate.

After formation of the underlayer film on the substrate, the underlayer film can be subjected to heating. Heating can complete removal of volatile components if they have not been removed during deposition and resting before heating. Drying and possibly the application of heat can help drive any further polymerization and/or crosslinking of the polymer forming component. Any heating step involved in the underlayer film formation should pay attention to potential thermal reactivity of the reactive gas releasing compounds, and heat may be purposely applied in part to induce release of a reactive may. Heating may be useful to more rapidly remove solvent or to cure or stabilize a polymer matrix. Heating of the underlayer film can generally be conducted in ambient conditions, though heating can also be conducted in inert environments, such as N₂, Ar, and the like, which can be desirable in embodiments in which underlayer components are sensitive to ambient gases. In some embodiments, heating can be conducted at a temperature from about 70° C. to about 600° C., from about 100° C. to about 500° C., from about 150° C. to about 400° C. in other embodiments, and from about 200° C. to about 300° C. in other embodiments. In some embodiments, heating can be conducted for durations from about 15 seconds to about 1,200 seconds, from about 30 seconds to about 600 seconds in other embodiments, and from about 45 seconds to about 300 seconds in further embodiments. A person of ordinary skill in the art will recognize that additional ranges within the explicit ranges above are contemplated and are within the present disclosure.

The thickness of the underlayer film can generally be controlled by deposition conditions and concentrations of precursor solutions. For example, for a spin coating deposition process, wafer spin speed can generally be tuned to afford desired film thicknesses. The initial wet film thickness determines the dry film thickness following removal of volatile components. In some embodiments, dry underlayer film thicknesses can be from about 5 nanometers (nm) to about 1000 nm, from about 10 nm to about 500 nm in other embodiments, and from about 15 nm to about 250 nm in other embodiments. A person of ordinary skill in the art will recognize that additional ranges within the explicit ranges above are contemplated and are within the present disclosure.

### Formation of Resist Coating

The underlayer materials described herein are particularly useful as underlayer films in lithographic processing of organometallic photoresists. As described above, some suitable examples of organometallic photoresists include organotin materials as disclosed in the above-referenced '684, '153, and '618 patents. In general, any suitable deposition method can be used to form a resist coating to the surface of the underlayer. In some embodiments, solution deposition methods can be used to form a resist coating. Some suitable coating approaches can include, for example, spin coating, spray coating, dip coating, knife edge coating, printing approaches, such as inkjet printing and screen printing, and the like. Some of these coating approaches form patterns of coating material during the coating process, although the resolution available currently from printing or the like has a significantly lower level of resolution than available from radiation-based patterning as described herein.

In some embodiments, vapor-based deposition methods can be used to form a resist coating on the surface of the underlayer. Suitable vapor-based deposition methods have been described in the above-referenced '618 patent and in U.S. Patent Application 2022/0308454 by Weidman et. al, entitled “Bake Strategies to Enhance Lithographic Performance of Metal-Containing Resist,” incorporated herein by reference. Potential deposition methods include, for example, physical vapor deposition (PVD), chemical vapor deposition (CVD), atomic layer deposition (ALD), or modifications thereof. For example, one or more gaseous hydrolytically-sensitive organotin compounds can be introduced to a reaction chamber and reacted with a co-precursor such as H₂O or its associated decomposition products, either in the gas phase or on a substrates surface, thereby producing a radiation sensitive organotin oxide hydroxide coating. If the hydrolysable compound is deposited on the surface with a subsequent hydrolysis reaction, this process can be considered a PVD deposition with in situ hydrolysis, but if the hydrolysis takes place during a continuous deposition process, it can be considered a CVD process. Likewise, if the hydrolysable precursor is sequentially adsorbed, chemisorbed, or decomposed on the substrate surface, and the residual film reacted with a second reactive precursor through multiple deposition/reaction cycles to deposit the corresponding organotin oxide hydroxide it can considered an ALD process. In some embodiments, processing may involve combinations of these PVD, CVD and ALD processes such that accurate terminology may be not as simple as the individual acronyms may suggest. Advantages of vapor deposition methods may include reduced resist film defect density, improved thickness and compositional uniformity, as well as conformal and side-wall coating of substrate topography. Disadvantages of vapor deposition may include deposition on chamber components other than the substrate, limitations on forming more complex layer compositions, a need for more specialized process equipment, and limitations to sufficiently volatile precursors.

In some embodiments, a wafer can be spun at rates from about 500 rpm to about 10,000 rpm, in further embodiments from about 1000 rpm to about 7500 rpm and in additional embodiments from about 2000 rpm to about 6000 rpm. The spinning speed can be adjusted to obtain a desired coating thickness. The spin coating can be performed for times from about 5 seconds to about 5 minutes and in further embodiments from about 15 seconds to about 2 minutes. An initial low speed spin, e.g., at 50 rpm to 250 rpm, can be used to perform an initial bulk spreading of the composition across the substrate. A back side rinse, edge bead removal step or the like can be performed with water or other suitable solvent to remove any edge bead. A person or ordinary skill in the art will recognize that additional ranges of spin coating parameters within the explicit ranges above are contemplated and are within the present disclosure.

The thickness of the resist coating generally can be a function of the deposition process parameters. For example, for spin coating, resist coating thickness can depend on the precursor solution concentration, viscosity and the spin speed used for spin coating. For other coating processes, the thickness can generally also be adjusted through the selection of the coating parameters. In some embodiments, it can be desirable to use a thin coating to facilitate formation of small and highly resolved features in the subsequent patterning process. For example, the coating materials after drying can have an average thickness of no more than about 1 microns, in other embodiments no more than about 250 nanometers (nm), in further embodiments no more than about 50 nm, in additional embodiments from a monolayer to about 50 nm, in other embodiments from about 1 nm to about 40 nm and in some embodiments from about 2 nm to about 25 nm. A person of ordinary skill in the art will recognize that additional ranges of thicknesses within the explicit ranges above are contemplated and are within the present disclosure.

The thickness can be evaluated using non-contact methods of x-ray reflectivity and/or ellipsometry based on the optical properties of the film. In general, the coatings are relatively uniform to facilitate processing. In some embodiments, the variation in thickness of the coating varies by no more than ±50% from the average coating thickness, in further embodiments no more than ±40% and in additional embodiments no more than about ±25% relative to the average coating thickness. In some embodiments, such as high uniformity coatings on larger substrates, the evaluation of coating uniformity may be evaluated with a 1 centimeter edge exclusion, i.e., the coating uniformity is not evaluated for portions of the coating within 1 centimeter of the edge. A person of ordinary skill in the art will recognize that additional ranges within the explicit ranges above are contemplated and are within the present disclosure.

After initial formation of the coating, the coated substrate can be heated in a post-apply bake (PAB) process order to drive densification of the resist coating. In embodiments in which heat is applied, the coating material can be heated to temperatures from about 45° C. to about 300° C., in other embodiments from about 55° C. to about 255° C., and in further embodiments from about 65° C. to about 225° C. The PAB can generally be performed for at least about 0.1 minute, in further embodiments from about 0.5 minutes to about 30 minutes and in additional embodiments from about 0.75 minutes to about 10 minutes. A person of ordinary skill in the art will recognize that additional ranges of heating temperature and times within the explicit ranges above are contemplated and are within the present disclosure.

### Exposure and Patterning

Following hydrolysis, condensation, and drying, the coating material can be finely patterned using radiation. The absorption of the radiation results in energy absorption that can break the Sn—C bonds between the metal and organic ligands so that at least some of the organic ligands are no longer available to stabilize the material. Radiolysis products, comprising organic ligands or fragments thereof, may diffuse out of the film, or not, depending on process variables and the identity of such products. With the absorption of a sufficient amount of radiation, the exposed coating material condenses, i.e. forms an enhanced metal oxo-hydroxo network, which may involve additional water absorbed from the process atmosphere. The radiation generally can be delivered according to a selected pattern. The radiation pattern is transferred to a corresponding pattern or latent image in the coating material with irradiated areas and un-irradiated areas. The irradiated areas comprise chemically altered coating material, and the un-irradiated areas comprise generally the as-formed coating material. As noted below, very smooth edges can be formed upon development of the coating material with the removal of the un-irradiated coating material or alternatively with selective removal of the irradiated coating material.

Radiation generally can be directed to the coated substrate through a mask or a radiation beam can be controllably scanned across the substrate. In general, the radiation can comprise electromagnetic radiation, an electron-beam (beta radiation), or other suitable radiation. In general, electromagnetic radiation can have a desired wavelength or range of wavelengths, such as visible radiation, ultraviolet radiation or x-ray radiation. The resolution achievable for the radiation pattern is generally dependent on the radiation wavelength, and a higher resolution pattern generally can be achieved with shorter wavelength radiation. Thus, it can be desirable to use ultraviolet light, x-ray radiation or an electron-beam to achieve particularly high-resolution patterns.

Following International Standard ISO 21348 (2007) incorporated herein by reference, ultraviolet light extends between wavelengths of greater than or equal 100 nm and less than 400 nm. A krypton fluoride laser can be used as a source for 248 nm ultraviolet light. The ultraviolet range can be subdivided in several ways under accepted Standards, such as extreme ultraviolet (EUV) from greater than or equal 10 nm to less than 121 nm and far ultraviolet (FUV) from greater than or equal to 122 nm to less than 200 nm A 193 nm line from an argon fluoride laser can be used as a radiation source in the FUV. EUV light has been used for lithography at 13.5 nm, and this light is generated from a Xe or Sn plasma source excited using high energy lasers or discharge pulses. Soft x-rays can be defined from greater than or equal 0.1 nm to less than 10 nm.

The amount of electromagnetic radiation can be characterized by a fluence or dose which is defined by the integrated radiative flux over the exposure time. Suitable radiation fluences can be from about 1 mJ/cm² to about 150 mJ/cm², in further embodiments from about 2 mJ/cm² to about 100 mJ/cm², and in further embodiments from about 3 mJ/cm² to about 50 mJ/cm². A person of ordinary skill in the art will recognize that additional ranges of radiation fluences within the explicit ranges above are contemplated and are within the present disclosure.

With electron-beam lithography, the electron beam generally induces secondary electrons which generally modify the irradiated material. The resolution can be a function at least in part of the range of the secondary electrons in the material in which a higher resolution is generally believed to result from a shorter range of the secondary electrons. Based on high resolution achievable with electron-beam lithography using the inorganic coating materials described herein, the range of the secondary electrons in the inorganic material is limited. Electron beams can be characterized by the energy of the beam, and suitable energies can range from about 5 V to about 200 kV (kilovolt) and in further embodiments from about 7.5 V to about 100 kV. Proximity-corrected beam doses at 30 kV can range from about 0.1 microcoulombs per centimeter squared to about 5 millicoulombs per centimeter squared (mC/cm²), in further embodiments from about 0.5 μC/cm² to about 1 mC/cm² and in other embodiments from about 1 μC/cm² to about 100 μC/cm². A person of ordinary skill in the art can compute corresponding doses at other beam energies based on the teachings herein and will recognize that additional ranges of electron beam properties within the explicit ranges above are contemplated and are within the present disclosure.

During irradiation, some amount of radiation can penetrate through the resist coating and into the underlayer coating to drive release of reactive gas such as H₂O and/or CO₂. These reactive gas can then migrate into the resist coating to react with reactive metal centers that have been created due to irradiation. For example, released water can react with the metal centers to create metal oxide and hydroxide moieties, and release CO₂ can react with the metal centers to drive formation of metal carbonate and bicarbonate moieties. In some embodiments, the underlayer can release labile reactive gas capable of reacting and/or coordinating with the organotin photoresist during or subsequent to irradiation. For example, some reactive gas can be thermally released, such as during a post exposure baking step to facilitate condensation of the irradiated material subsequent to irradiation. In some embodiments, the irradiation can be performed with an EUV source, in other embodiments the irradiation can be performed with an ultraviolet source, and in other embodiments the irradiation can be performed with an ion source. In some embodiments, a second irradiation with an ultraviolet or visible radiation source can be performed after an initial EUV irradiation step. A second irradiation with an ultraviolet or visible radiation source may be performed before or after a post exposure bake step described below. In such a secondary irradiation step, the underlayer can release a reactive gas into the resist layer to drive beneficial reactions that can boost development contrast. Release of water into the irradiated patterning material after EUV irradiation, for example, can enhance hydrolysis, i.e., increase of Sn—OH concentration, in the irradiated regions. In some embodiments, the substrate can be heated during the second irradiation step using an ultraviolet or visible radiation source. In embodiments wherein the substrate is heated during irradiation with ultraviolet or visible radiation, the substrate can be heated from about 45° C. to about 300° C., in additional embodiments from about 50° C. to about 250° C., in further embodiments from about 60° C. to about 220° C. and in other embodiments form about 100° C. to about 200° C. With respect to these ranges, suitable ranges explicitly include any combination of these upper and lower temperatures, such as from about 100° C. to about 300° C. A person of ordinary skill in the art will recognize that additional ranges of heating temperature within the explicit ranges above are contemplated and are within the present disclosure.

Based on the design of the coating material, there can be a large contrast of material properties between the irradiated regions that have condensed coating material and the un-irradiated, coating material with substantially intact organic ligands. It has been found that the contrast at a given dose can be improved with a post-irradiation heat treatment, although satisfactory results can be achieved in some embodiments without post-irradiation heat treatment. The post-exposure bake (PEB) can be desired to anneal the irradiated coating material to increase its condensation without significantly condensing the un-irradiated regions of coating material based on thermal breaking of the organic ligand-metal bonds. For appropriate embodiments, the reactive gas in the underlayer can be released thermally during a post-exposure bake. For these embodiments, the suitable temperature for release of the reactive gas may influence the selected temperature of the post exposure bake, but these temperatures are generally still within the following ranges. For embodiments in which a PEB is used, the post-irradiation heat treatment can be performed at temperatures from about 45° C. to about 300° C., in additional embodiments from about 50° C. to about 250° C., in further embodiments from about 60° C. to about 220° C. and in other embodiments form about 100° C. to about 200° C. With respect to these ranges, suitable ranges explicitly include any combination of these upper and lower temperatures, such as from about 100° C. to about 300° C. The post exposure heating can generally be performed for at least about 0.1 minute, in further embodiments from about 0.5 minutes to about 30 minutes and in additional embodiments from about 0.75 minutes to about 10 minutes. A person of ordinary skill in the art will recognize that additional ranges of post-irradiation heating temperature and times within the explicit ranges above are contemplated and are within the present disclosure. In embodiments wherein a second irradiation step is performed with ultraviolet or visible light after the PEB, a second PEB can be performed at similar conditions as described above after the second irradiation step. This high contrast in material properties further facilitates the formation of high-resolution lines with smooth edges in the pattern following development as described in the following section.

In some embodiments, the reactive gas releasing compounds of the resist underlayer can release reactive gas during heating, such as during the PEB step. As described above, irradiation of the resist coating can induce formation of reactive metal centers which can readily react with water and/or CO₂ to form polymeric metal oxide/hydroxide species and/or metal carbonate/bicarbonate species that are resistant to a subsequent development step.

### Development

After patterning the resist coating with a suitable radiation source, the resist can then be developed in an appropriate developer solution. Some useful developer compositions for these organotin oxide photoresists have been described in published U.S. Patent Application No. 2020/0326627 A1 (the '627 application) by Jiang et al., incorporated herein by reference. Owing to their compositions comprising both metal oxide hydroxide and organic ligands, it has been shown that both positive tone and negative tone patterning can be achieved in an organotin oxide hydroxide system. For example, when an organic solvent is used as a developer then negative tone patterning is realized wherein the unexposed material is dissolved away and the exposed material remains. In contrast, when an aqueous acid or base solution, for example comprising tetra alkyl ammonium hydroxide, is used as a developer then positive tone patterning can be realized wherein the exposed material is dissolved away and the unexposed material remains.

For the negative tone imaging, the developer can comprise an organic solvent, such as the solvents used to form the precursor solutions. The developer solvent can also comprise one or more solvents in a blended composition. In general, selection of appropriate developer solvent compositions can be influenced by solubility parameters with respect to the coating material, both irradiated and non-irradiated, as well as developer volatility, flammability, toxicity, viscosity, and potential chemical interactions with other process material. In particular, suitable developer solvents include, for example, aromatic compounds (e.g., benzene, xylenes, toluene), esters (e.g., propylene glycol monomethyl ester acetate, ethyl acetate, ethyl lactate, n-butyl acetate, butyrolactone), alcohols (e.g., 4-methyl-2-pentanol, 1-butanol, isopropanol, 1-propanol, methanol), ketones (e.g., methyl ethyl ketone, acetone, cyclohexanone, 2-heptanone, 2-octanone), ethers (e.g., tetrahydrofuran, dioxane, anisole) and the like. The developer composition can further comprise one or more organic acids, such as carboxylic acids (e.g., formic acid, acetic acid, pivalic acid, oxalic acid, etc.), such as described in the '627 application referenced above. The development can be performed for about 5 seconds to about 30 minutes, in further embodiments from about 8 seconds to about minutes and in addition embodiments from about 10 seconds to about 10 minutes. A person of ordinary skill in the art will recognize that additional ranges within the explicit ranges above are contemplated and are within the present disclosure.

For positive tone imaging, the developer generally can comprise aqueous acids or bases. In some embodiments, aqueous bases can be used to obtain sharper images. To reduce contamination from the developer, it can be desirable to use a developer that does not have metal atoms. Thus, quaternary ammonium hydroxide compositions, such as tetraethylammonium hydroxide, tetrapropylammonium hydroxide, tetrabutylammonium hydroxide or combinations thereof, are desirable as developers. In general, the quaternary ammonium hydroxides of particular interest can be represented with the formula R₄NOH, where R=a methyl group, an ethyl group, a propyl group, a butyl group, or combinations thereof. The coating materials described herein generally can be developed with the same developer commonly used presently for polymer resists, specifically tetramethyl ammonium hydroxide (TMAH). Commercial TMAH is available at 2.38 weight percent, and this concentration can be used for the processing described herein. Furthermore, mixed quaternary tetra alkyl-ammonium hydroxides can be used. In general, the developer can comprise from about 0.5 to about 30 weight percent, in further embodiments from 30 about 1 to about 25 weight percent and in other embodiments from about 1.25 to about 20 weight percent tetra-alkylammonium hydroxide or similar quaternary ammonium hydroxides. A person of ordinary skill in the art will recognize that additional ranges of developer concentrations within the explicit ranges above are contemplated and are within the present disclosure.

It has also been discovered that solventless development, also referred to as dry development, can be employed with organotin materials. Dry development can include, for example, selective removal of the irradiated or non-irradiated regions of the photoresist by exposing the material to an appropriate plasma or appropriate flowing gas. Dry development of organotin resists has been described in PCT Publication No. 2020/132281A1 by Volosskiy et al, entitled “Dry Development of Resists”, and in pending U.S. provisional application No. 63/247,885 by Cardineau et. al, entitled “High Resolution Latent Image Processing and Thermal Development”, both of which are incorporated herein by reference. In such dry development processes, development can be achieved by exposing the irradiated substrate to a plasma or a thermal process while flowing a gas comprising an appropriate developer composition, such as a halide composition (e.g., comprising F, Cl, Br, I), an alcohol, a carboxylic acid, an amine, and others.

Following development, the developed structure can generally be dried by heating the structure at an appropriate temperature for a desired amount of time. Temperatures for this final drying step are not particularly limited. In some embodiments, the anneal can be between 100° C. and 500° C., in other embodiments from 200° C. to 500° C., and from 300° C. to 400° C. in further embodiments. A person of ordinary skill in the art will recognize that additional ranges within the explicit ranges above are contemplated and are within the present disclosure.

### EXAMPLES

### Example 1: Synthesis of a Reactive Gas Releasing Compound

This example demonstrates the synthesis of compound A1-2.

Methyl 4-formyl-3-nitrobenozate (3.9 g) was dissolved in EtOH (100 mL). The solution was cooled to 0° C. Then, while stirring, sodium borohydride (0.2 g) was added, and the contents were allowed to warm to room temperature. After stirring the contents at room temperature for 6 hours, solvent was removed in vacuo and further purified by extraction with Et₂O to yield a crude product compound as a colorless liquid following removal of the ether. The crude material was further purified with silica column chromatography using a solvent blend of 50 vol % hexane and 50 vol % ethyl acetate. The collected fraction was dissolved in a mixture of MeOH (50 mL) and tetrahydrofuran (THF) (50 mL), then aqueous KOH (100 g) was added. The mixture was refluxed for 5 hours and then the solvents were removed in vacuo. Then, 2 M aqueous HCl was added and stirred at room temperature for 30 minutes. The HCl solution was extracted with dichloromethane and then the solvents were removed in vacuo. The obtained material was then dissolved in dichloromethane (20 mL) and triphenylsulfonium chloride (1.0 g) and aqueous NaHCO₃ (1.0 M, 20 mL). The mixture was stirred for 3 hours. Then 50 mL of dichloromethane was added. The product was extracted and the solvents were again removed in vacuo. The product compound was characterized by H NMR.

### Example 2: Synthesis of a Polymer Composition

This example demonstrates the two-part synthesis of a polymer composition for use in an underlayer composition.

Part A: Synthesis of a Polycarbosilane (Compound b-1) Precursor Polymer

This synthesis followed the procedure in the '575 application cited above. Into a nitrogen-substituted, first reaction vessel, 5.83 g of magnesium powder and 11 g of tetrahydrofuran were charged. The mixture was kept at 20° C. and stirred until well blended. In a separate vessel, 17.38 g of dibromo methane (0.10 mol) and 13.54 g of trichlorosilane (0.10 mol) were dissolved in 111 g of tetrahydrofuran to prepare a monomer solution. The monomer solution was added dropwise into the first reaction vessel while stirring and while maintaining the nitrogen-substituted environment. The dropwise addition required approximately 1 hour to complete. Subsequently, the mixture was warmed to 40° C. and allowed to react for 1 hour. The mixture was then warmed to 60° C. and allowed to further react for another 3 hours. Next, 67 g of tetrahydrofuran was added to the reaction mixture, and the mixture was then cooled to about 0-10° C. to yield a polymerization reaction liquid. While stirring, a 30.36 g aliquot of triethylamine was first added to the polymerization reaction liquid, and then 9.61 g of methanol was added dropwise. The dropwise addition required approximately 10 minutes to complete. Subsequently, the mixture was warmed to 20° C. and allowed to react for 1 hour. The reaction liquid was poured into 220 g of diisopropyl ether and a crude product was formed as a precipitate. The crude product was collected by filtration and an evaporator was used to remove solvents from the crude product. The resulting material was mixed into 50 g of diisopropyl ether. The solid material was collected by filtration and then an evaporator was used to remove the remaining solvent to yield 63 grams of a polycarbosilane (compound B-1), a white solid having a weight average molecular weight of 900 as measured by Gel Permeation Chromatography (GPC) measurement. A polycarbosilane solution was prepared by adding 900 ml of methyl isobutyl ketone to 63 grams of compound B-1.

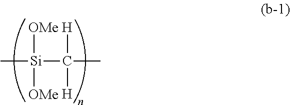

### Part B: Synthesis of Polymer Composition (Compound B-1)

Into a reaction vessel, 100 g of the polycarbosilane solution in diisopropyl ether obtained in Part A and 90 g of methanol were charged. The contents were warmed to 30° C., then 8 g of a 3.2% by mass aqueous oxalic acid solution was added dropwise into the reaction vessel while stirring. The dropwise addition required approximately 20 min to complete. Subsequently, the mixture was warmed to 40° C. and allowed to react for 4 hours. The mixture was then cooled to about 20-30° C. Next, 99 g of diisopropyl ether and 198 g of water were added to the reaction vessel and liquid separation extraction was conducted. To the organic layer obtained, 0.26 g of oxalic acid dihydrate and 396 g of propylene glycol monomethyl ether acetate were added while stirring. An evaporator was used to reduce the solution volume by about half so as to remove the water, diisopropyl ether, alcohols produced by the reaction, and excess propylene glycol monomethyl ether acetate (PGMEA). To the solution thus obtained, which is believed to maintain roughly half the volume of PGMEA, 19.82 g of trimethyl orthoformate was added. The trimethyl orthoformate was used as a dehydrating agent. The mixture was warmed to 40° C. and allowed to react for 1 hour. Then the mixture was cooled to a temperature of about 20-30° C. and 99 g of propylene glycol monomethyl ether acetate was added while stirring. An evaporator was used to reduce the solution volume by about half so to remove esters and alcohols produced by the reaction, unreacted trimethyl orthoformate, and excess propylene glycol monomethyl ether acetate to give a 5% by mass solution of a polymer composition (compound B-1) in propylene glycol monomethyl ether acetate. The concentration of the solution (% by mass) was determined by baking 0.5 g of the solution of the compound B-1 at 250° C. for 30 min; measuring a mass of a residue thus obtained; and dividing the mass of the residue by the mass of the solution used (0.5 g). Compound B-1 is represented by the formula (B-1), with the subscript “w” representing the relative ratio of repeat units which are crosslinked via an Si—O—Si linkage, wherein w+x=1. The weight average molecular weight of compound B-1 was 2,500, as measured by gel permeation chromatography.

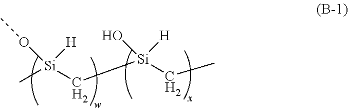

### Example 3: Underlayer Compositions

This example describes the preparation of a set of underlayer formulations which utilize the polymer prepared according to Example 2.

Underlayer formulations J-1 to J-3 were prepared by mixing a reactive gas releasing compound (A), a polymer compound (B), a solvent (C), and an orthoester (D) according to Table 1. Underlayer formulation J-0 was prepared by mixing a polymer compound (B), a solvent (C), and an orthoester (D) according to Table 1. Polymer compound (B) was provided as a 5% by mass solution, the preparation of which is described in Example 2. For each formulation, the amount of component (B) refers to a mass of the neat polymer and the mass of component (C) refers to the total mass of propylene glycol methyl ether acetate (PGMEA) solvent, including the PGMEA solvent contained in the solution of the compound (B). Each formulation was filtered through a 0.2 μm syringe filter.

TABLE 1

| | (A) | | (B) | | (C) | | (D) | |
|---|---|---|---|---|---|---|---|---|
| | | Amount | | Amount | | Amount | | Amount |
| Formulation | Type | (mass %) | Type | (mass %) | Type | (mass %) | Type | (mass %) |
| J-1 | 2-nitrobenzyl | 0.01 | B-1 | 1.00 | PGMEA | 95.99 | trimethyl | 3.00 |
| | alcohol (A1-1) | | | | | | orthoformate | |
| J-2 | 2-nitrobenzyl | 0.03 | B-1 | 1.00 | PGMEA | 95.97 | trimethyl | 3.00 |
| | alcohol (A1-1) | | | | | | orthoformate | |
| J-3 | 2-nitrobenzyl | 0.05 | B-1 | 1.00 | PGMEA | 95.95 | trimethyl | 3.00 |
| | alcohol (A1-1) | | | | | | orthoformate | |
| J-0 | — | — | B-1 | 1.00 | PGMEA | 96.00 | trimethyl | 3.00 |

### Example 4: Lithographic Performance

This example describes the lithographic performance of photoresist deposited onto a set of underlayer films prepared using the underlayer formulations described in Example 3.

Each of the formulations shown in Table 3 was individually spin coated onto one of four 300 mm Si wafers using a TEL CLEAN wafer track and baked at 220° C. for 1 minute to provide a set of underlayer-coated wafers. Each underlayer film had a thickness of about 10 nm. Inpria YATU1011 photoresist was then deposited on each underlayer-coated wafer by spin-coating. The wafers were baked at 100° C. for 1 minute. Each resist film had a thickness of about 22 nm. The films were exposed to EUV radiation with an ASML NXE Twin Scan 3400 exposure tool using a Hex Pillar mask having an x-y pitch of 66 nm-38 nm (Px66y38) with a target critical dimension (CD) of 22 nm, using a dose meander exposure scheme from 50 mJ to 142 mJ. The underlayer is expected to release H₂O as a result of the irradiation. After EUV exposure, each wafer was baked at 180° C. for 1 minute. Development was carried out for each wafer with a 5 vol. % acetic acid in PGMEA followed by a final hard bake at 250° C. for 1 minute. Exposure fields were measured by CD-SEM. Images captured for target 22 nm CD pillars on the Px66y38y pattern were analyzed for LCDU, and the results are shown in Table 2 below. LCDU is the local critical dimension uniformity, which is used in EUV patterning to evaluate arrays of features, such as variation in critical dimension between adjacent holes or pillars in arrays. The evaluation of LCDU is described, for example, in Kong et al., “Measuring Local CD Uniformity in EUV vias with scatterometry and machine learning,” 2020, Proc. of SPIE Vol. 11325 113251I-1, incorporated herein by reference.

TABLE 2

| | Formulation for | Dose | |
|---|---|---|---|
| Sample | Underlayer Composition | (mJ/cm²) | LCDU (nm) |
| S-1 | J-1 | 83.5 | 2.1 |
| S-2 | J-2 | 84.6 | 1.9 |
| S-3 | J-3 | 85.3 | 1.9 |
| S-0 | J-0 | 87.3 | 2.0 |

The data in Table 2 shows that the samples prepared with additive-containing underlayers (samples S-1 to S-3) achieved the 22 nm CD on the selected pattern with a lower dose than the sample prepared without an additive-containing underlayer (S-0). The results indicate that the additive in the underlayer can improve the sensitivity of the resist without increasing the LCDU. The data shows that the LCDU for the samples with higher additive-loaded underlayers (S-2 and S-3) are lower than the LCDU for the non-additive-loaded underlayer (S-0). These results suggests that the additive in the underlayer may enhance lithographic performance by facilitating the achievement of both an increased resist sensitivity and a lower patterned feature roughness.

### Example 5: Formulation Study

This example illustrates the effect of additive composition and processing temperature on the amount of a reactive gas, in this case carbon dioxide, generated from an underlayer coating during thermal processing.

### General Coating and Processing Steps

A set of underlayer formulations were prepared by mixing a reactive gas releasing compound (A) and a polymer compound (B) in the amounts according to Table 3 and dissolving the compounds in PGMEA to form a solution having a solute concentration of approximately 0.5 mass %. A formulation for a control sample (sample 5-6) was prepared similarly by dissolving polymer compound (B) in PGMEA to form a solution having a polymer concentration of approximately 0.5 mass %. Each of the formulations was individually spin coated onto a 300 mm Si wafers using a TEL CLEAN wafer track to provide a set of each of Samples 5-1 to 5-6. Each underlayer film had a thickness of about 50 nm. The additive amounts shown in Table 3 provided for an equimolar concentration of the chosen additive in the underlayers of Samples 5-1 to 5-5.

TABLE 3

| Formulation | |
|---|---|
| (A) | (B) |

| | | Amount | | Amount |
|---|---|---|---|---|
| Sample | Type | (mass %) | Type | (mass %) |
| 5-1 | Meldrum's | 0.69 | B-1 | 99.31 |
| | Acid | | | |
| | (A2-15) | | | |
| 5-2 | Propylene | 0.49 | B-1 | 99.51 |
| | Carbonate | | | |
| | (A2-8) | | | |
| 5-3 | PBG-1 | 1.53 | B-1 | 98.47 |
| | (A2-12) | | | |
| 5-4 | PBG-2 | 1.66 | B-1 | 98.34 |
| | (A2-13) | | | |
| 5-5 | PBG-3 | 1.67 | B-1 | 98.33 |
| | (A2-14) | | | |
| 5-6 | — | — | B-1 | 100 |

### Evaluation Method

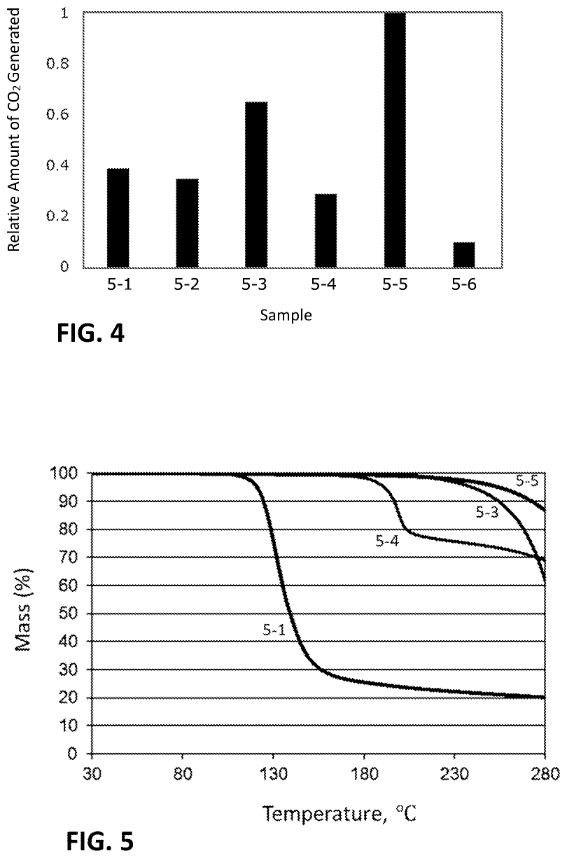

Each of the first set of samples 5-1 to 5-6 was deposited into a sealed testing chamber of a headspace gas chromatography mass spectrometry (HS-GC-MS) analyzer (JTD-505III (JAI)/J<S-Q1500GC (JEOL)). The testing chamber was provided with an air environment. The samples were baked at 220° C. for 1 minute, and the amount of CO₂ generated was measured. FIG. 4 shows the results of the GC-MS analysis by plotting the relative amount of CO₂ generated for each of samples 5-1 to 5-6. For samples with reactive gas releasing compound (A), the relative amount of CO₂ generated was calculated by normalizing the measured amount of CO₂ with the mass % of each additive shown in Table 3. FIG. 4 shows that sample 5-5 generated the highest relative amount of CO₂, followed by sample 5-3.

Each of the second set of samples 5-1 to 5-6 was deposited into a sealed testing chamber for thermogravimetry-differential thermal analysis (TG-DTA) testing (TG-DTA2000SR(NETZSCH)). The testing chamber was provided with a nitrogen environment. Each sample was subjected to gradual chamber temperatures increases from room temperature to 280° C. FIG. 5 shows the thermogravimetric results by plotting the mass percent of sample 5-1 and 5-3 to 5-5 as a function of the chamber temperature. Sample 5-1 showed an onset of mass loss at about 120° C. Sample 5-4 showed an onset of mass loss at about 190° C., and samples 5-3 and 5-5 showed an onset of mass loss at about 220° C. The results show that the thermal stability of the additives is a function of temperature.

The results suggest that the additive type and processing conditions can be used to control the concentration of a reactive gas, such as CO₂, in the processing environment, which can lead to improved patterning performance relative to standard processing.

### Further Inventive Concepts

1. A multilayer structure comprising:
a substrate with a surface, an underlayer material over at least a portion of the substrate surface, and an organometallic patterning material that is radiation sensitive over at least a portion of the underlayer material, wherein the underlayer material comprises a polymer and a reactive gas releasing moiety, which may or may not be bonded to the polymer, wherein the reactive gas releasing moiety releases a metal ligand forming molecule in response to radiation and/or heat.
   2. The multilayer structure of inventive concept 1 wherein the metal ligand forming molecule comprises H₂O, CO₂, an alcohol, or a combination thereof
   3. The multilayer structure of inventive concept 1 wherein the underlayer material releases the metal ligand forming molecule in response to EUV radiation.
   4. The multilayer structure of inventive concept 1 wherein the underlayer material releases the metal ligand forming molecule in response to ultraviolet or visible radiation.
   5. The multilayer structure of inventive concept 1 wherein the reactive gas releasing moiety comprises a nitrobenzyl functional group, a nitrobenzyl alcohol, an ethylene glycol moiety, an alcohol, Meldrum's acid group, a propylene carbonate functional group, a photobase generator with an aromatic group bonded to an amine through a carbamate linkage, or mixtures thereof.
   6. The multilayer structure of inventive concept 1 wherein the underlayer material further comprises an acid generator.
   7. The multilayer structure of inventive concept 1 wherein the underlayer material has an average thickness from about 5 nm to about 500 nm and comprises at least about 0.001 wt % of a gas releasing compound comprising the reactive gas releasing moiety and a polymer selected from a novolac resin, a resol resin, a styrene resin, an acenaphthylene resin, an indene resin, an arylene resin, a calixarene resin, a copolymer thereof, a fluorinated derivative thereof, a polysiloxane, a polyethylene-polyester copolymer, or mixtures thereof.
   8. The multilayer structure of inventive concept 1 wherein the organometallic patterning material comprises radiation sensitive metal-carbon bonds and/or metal-carboxylate bonds.
   9. The multilayer structure of inventive concept 1 wherein the organometallic patterning material comprises an alkyltin oxide hydroxide approximately represented by the formula R_{z}SnO_{(2-z/2-x/2)} (OH)ₓ, where 0<x<3, 0<z≤2, x+z≤4, and R is a hydrocarbyl group forming a carbon bond with the tin atom.
   10. The multilayer structure of inventive concept 9 wherein R comprises a hydrocarbyl group with 1-31 carbon atoms or a blend of distinct hydrocarbyl groups each with 1-31 carbon atoms and z is about 1.
   11. The multilayer structure of inventive concept 9 wherein R comprises a branched alkyl, a cycloalkyl, an alkenyl, an aryl, an allylic, or an alkynyl, or combinations thereof.
   12. The multilayer structure of inventive concept 9 wherein R comprises t-butyl, t-amyl, i-propyl, n-butyl, methyl, or combinations thereof.
   13. The multilayer structure of inventive concepts 9-12 wherein R comprises a hydrocarbyl group substituted with hetero-atom functional groups.
   14. The multilayer structure of inventive concept 13 wherein the hetero-atom functional groups comprise cyano, thio, silyl, ether, keto, ester, or halogenated groups or combinations thereof.
   15. The multilayer structure of inventive concept 1 wherein the substrate is a semiconductor wafer.
   16. A method for patterning a radiation sensitive organometallic composition, the method comprising:
coating a composition comprising a reactive gas releasing moiety onto a surface of a substrate to form an underlayer material that covers at least a portion of the surface to form an underlayer structure;
depositing an organometallic patterning material on the underlayer structure to form a multilayer structure;
irradiating the multilayer structure according to a selected pattern to form a latent image; heating the irradiated multilayer structure with the latent image as a post-exposure bake, wherein the underlayer material releases a metal ligand forming molecule in response to irradiation or heating through the underlayer material or a portion thereof, wherein the organometallic patterning material or portion thereof reacts with the metal ligand forming molecule; and
developing the latent image after the post exposure bake and reaction with the metal ligand forming molecule.
   17. The method of inventive concept 16 wherein the composition further comprises a matrix forming species and an organic solvent, wherein the matrix forming species comprises a polymer and/or one or more polymer precursors and wherein the metal ligand forming molecule comprises H₂O, CO₂, an alcohol, or a combination thereof.
   18. The method of inventive concept 16 wherein the reactive gas releasing moiety comprises a nitrobenzyl functional group, a nitrobenzyl alcohol, an ethylene glycol moiety, an alcohol, a Meldrum's acid group, a propylene carbonate functional group, a photobase generator with an aromatic group bonded to an amine through a carbamate linkage, or mixtures thereof.
   19. The method of inventive concept 16 wherein coating and/or depositing comprises spin coating, spray coating, dip coating, knife edge coating, and/or printing approaches.
   20. The method of inventive concept 16 wherein depositing comprises vapor deposition and/or wherein developing is a dry development process performed with a developing reactive gas or with a plasma.
   21. The method of inventive concept 16 wherein heating is performed at about 45° C. to about 300° C. for at least about 0.1 minutes.
   22. The method of inventive concept 16 wherein the irradiating is performed with EUV radiation, UV radiation, electron beam radiation, or a combination thereof.
   23. The method of inventive concept 16 wherein irradiating is at a dose of electromagnetic radiation of no more than 100 mJ/cm².
   24. The method of inventive concept 16 wherein irradiating is performed with EUV radiation and wherein the method further comprises, following irradiating with EUV radiation, irradiating the multilayer structure with ultraviolet or visible light.
   25. The method of inventive concept 24 wherein irradiating with ultraviolet or visible light is performed before heating the irradiated multilayer structure with the latent image as a post-exposure bake.
   26. The method of inventive concept 24 wherein irradiating with ultraviolet or visible light is performed after heating the irradiated multilayer structure with the latent image as a post-exposure bake and before developing.
   27. The method of inventive concept 26 further comprising, after irradiating with ultraviolet or visible light and before developing, heating the irradiated multilayer structure at about 45° C. to about 300° C.
   28. The method of any of inventive concepts 24-27 further comprising heating the irradiated the multilayer structure at about 45° C. to about 300° C. during irradiating with ultraviolet or visible light.
   29. The method of inventive concept 16 wherein the substrate comprises a semiconductor wafer.
   30. A polymeric material comprising a CO₂ releasing moiety and a polymer material wherein the CO₂ releasing moiety releases CO₂ in response to radiation or heat and wherein the polymer material provides a matrix for the CO₂ releasing moiety.
   31. The polymeric material of inventive concept 30 wherein the polymer material comprises a novolac resin, a resol resin, a styrene resin, an acenaphthylene resin, an indene resin, an arylene resin, a calixarene resin, a copolymer thereof, a fluorinated derivative thereof, a polysiloxane, a polycarbosilane, a polyethylene-polyester copolymer, or mixtures thereof.

The embodiments above are intended to be illustrative and not limiting. Additional embodiments are within the claims. In addition, although the present invention has been described with reference to particular embodiments, those skilled in the art will recognize that changes can be made in form and detail without departing from the spirit and scope of the invention. Any incorporation by reference of documents above is limited such that no subject matter is incorporated that is contrary to the explicit disclosure herein. To the extent that specific structures, compositions and/or processes are described herein with components, elements, ingredients or other partitions, it is to be understand that the disclosure herein covers the specific embodiments, embodiments comprising the specific components, elements, ingredients, other partitions or combinations thereof as well as embodiments consisting essentially of such specific components, ingredients or other partitions or combinations thereof that can include additional features that do not change the fundamental nature of the subject matter, as suggested in the discussion, unless otherwise specifically indicated. The use of the term “about” herein refers to imprecision due to the measurement for the particular parameter as would be understood by a person f ordinary skill in the art, unless explicitly indicated otherwise.

What is claimed is:

1. A film-forming composition comprising a flowable blend of a reactive gas releasing moiety, a matrix forming species, an organic solvent, and an optional activating additive, wherein the reactive gas releasing moiety releases metal ligand forming molecules in response to radiation or heat, wherein the activating additive is present if the gas releasing moiety releases the reactive gas upon activation stimulated by the activating additive and wherein the matrix forming species comprises a polymer and/or one or more polymer precursors.

2. The composition of claim 1 wherein the metal ligand forming molecules comprise H₂O, CO₂, an alcohol, or a combination thereof.

3. The composition of claim 1 wherein the reactive gas releasing moiety comprises a nitrobenzyl functional group, a nitrobenzyl alcohol functional group, a Meldrum's acid group, a propylene carbonate functional group, nitrobenzyl alcohol or derivatives thereof, ethylene glycol or derivatives thereof, an alcohol, a photobase generator with an aromatic group bonded to an amine through a carbamate linkage, or mixtures thereof.

4. The composition of claim 1 wherein the reactive gas releasing moiety is covalently bonded to the matrix forming species.

5. The composition of claim 1 further comprising an orthoester, a photoacid generator or a combination thereof.

6. The composition of claim 1 wherein the matrix forming species comprises precursors of novolac resins, resol resins, styrene resins, acenaphthylene resins, indene resins, arylene resins, or calixarene resins, a copolymer thereof, a fluorinated derivative thereof, a polysiloxane, a polycarbosilane, a polyethylene-polyester copolymer, or mixtures thereof.

7. The composition of claim 1 wherein the organic solvent comprises an alcohol, a ketone, an ether, an ester, or combinations thereof.

8. The composition of claim 1 wherein the activating additive comprises a photoacid generator (PAG), a thermal acid generator (TAG), or a combination thereof.

9. The composition of claim 8 wherein the photoacid generator comprises 2,4,4,6-tetrabromocyclohexadienone, benzoin tosylate, 2-nitrobenzyl tosylate, an alkyl sulfonate, an onium salt, or combinations thereof.

10. The composition of claim 1 wherein the activating additive comprises a sulfonium sulfonate, an iodonium sulfonate, a N-sulfonic imides, and/or a N-sulfonic imine covalently bonded to the matrix forming species.

11. The composition of claim 1 wherein the composition comprises from about 0.001 wt % to about 5 wt % of the reactive gas releasing moiety, from about 0.1 wt % to about 20 wt % of the matrix forming species, from about 60 wt % to about 99.9 wt % of the organic solvent, and from about 0 to about 15 wt % of the activating additive.

12. A composition comprising a blend of a reactive gas releasing moiety, a polymer matrix, and an optional activating additive, wherein the reactive gas releasing moiety releases metal ligand forming molecules in response to radiation or heat, wherein the activating additive is present if the gas releasing moiety releases the reactive gas upon activation stimulated by the activating additive, and wherein the reactive gas releasing moiety is bound to the polymer matrix or is blended within the polymer matrix.

13. The composition of claim 12 wherein the metal ligand forming molecules comprise H₂O, CO₂, an alcohol, or a combination thereof.

14. The composition of claim 12 wherein the reactive gas releasing moiety comprises a nitrobenzyl functional group, a nitrobenzyl alcohol functional group, a Meldrum's acid group, a propylene carbonate functional group, nitrobenzyl alcohol or derivatives thereof, ethylene glycol or derivatives thereof, an alcohol, a photobase generator with an aromatic group bonded to an amine through a carbamate linkage, or mixtures thereof.

15. The composition of claim 12 wherein the reactive gas releasing moiety is covalently bonded to the polymer matrix.

16. The composition of claim 12 further comprising an orthoester, a photoacid generator or a combination thereof.

17. The composition of claim 12 wherein the polymer matrix comprises a novolac resin, a resol resin, a styrene resin, an acenaphthylene resin, an indene resin, an arylene resin, a calixarene resin, a copolymer thereof, a fluorinated derivative thereof, a polysiloxane, a polycarbosilane, a polyethylene-polyester copolymer, or mixtures thereof.

18. The composition of claim 12 wherein the activating additive comprises a photoacid generator (PAG), a thermal acid generator (TAG), or a combination thereof.

19. The composition of claim 18 wherein the photoacid generator comprises 2,4,4,6-tetrabromocyclohexadienone, benzoin tosylate, 2-nitrobenzyl tosylate, an alkyl sulfonate, an onium salt, or combinations thereof.

20. The composition of claim 12 wherein the activating additive comprises a sulfonium sulfonate, an iodonium sulfonate, a N-sulfonic imides, and/or a N-sulfonic imine covalently bonded to the polymer matrix.

21. The composition of claim 12 wherein the reactive gas releasing moiety releases metal ligand forming molecules in response to EUV radiation.

22. The composition of claim 12 wherein the reactive gas releasing moiety releases metal ligand forming molecules in response to ultraviolet or visible radiation.

23. The composition of claim 12 wherein the reactive gas releasing moiety releases metal ligand forming molecules in response to heat.

24. The composition of claim 12 wherein the composition is in a layer on a substrate and wherein the composition comprises from about 0.01 wt % to about 20 wt % of the reactive gas releasing moiety, from about 50 wt % to about 99 wt % of the matrix forming species, and from about 0 to about 50 wt % of the activating additive.
